(19) United States
(12) Patent Application Publication
(10) Pub. No.: US 2024/0395878 A1
(43) Pub. Date: Nov. 28, 2024

(54) SEMICONDUCTOR DEVICE AND METHOD OF MANUFACTURING THE SAME

(71) Applicant: Renesas Electronics Corporation, Tokyo (JP)

(72) Inventors: Yuta NABUCHI, Tokyo (JP); Akihiro SHIMOMURA, Tokyo (JP)

(21) Appl. No.: 18/630,051

(22) Filed: Apr. 9, 2024

(30) Foreign Application Priority Data
May 26, 2023 (JP) 2023-087205

(51) Int. Cl. H01L 29/40; H01L 29/06; H01L 29/66; H01L 29/78

(52) U.S. Cl. CPC H01L 29/407; H01L 29/0696; H01L 29/401; H01L 29/66734; H01L 29/7813

(57) ABSTRACT

A trench TR1 and a trench TR2 are formed in a semiconductor substrate SUB so as to reach a predetermined depth from the upper surface (TS) of the semiconductor substrate SUB. A field plate electrode FP is formed at a lower portion of the trench TR1, and a gate electrode GE1 is formed at an upper portion of the trench TR1. A gate electrode GE2 is formed inside the trench TR2. The depth of the trench TR1 is deeper than the depth of the trench TR2. The trench TR1 extends in the Y direction, and the trench TR2 extends in the X direction. The trench TR1 and the trench TR2 are in communication with each other. The gate electrode GE1 and the gate electrode GE2 are integrated with each other.

### CROSS-REFERENCE TO RELATED APPLICATIONS

The disclosure of Japanese Patent Application No. 2023-087205 filed on May 26, 2023, including the specification, drawings and abstract is incorporated herein by reference in its entirety.

### BACKGROUND

The present disclosure relates to a semiconductor device and method of manufacturing the same, and more particularly, to a semiconductor device and a method of manufacturing the same including a gate electrode and a field plate electrode inside a trench.

In a semiconductor device including a semiconductor element such as a power MOSFET (Metal Oxide Semiconductor Field Effect Transistor), a trench gate structure in which a gate electrode is embedded in a trench is applied.

For example, Patent Document 1 discloses a split gate structure in which a field plate electrode is formed at a lower portion of a trench and a gate electrode is formed at an upper portion of the trench as a type of a trench gate structure. A source potential is supplied from the source electrode to the field plate electrode. By expanding the depletion layer from the field plate electrode to the drift region, the breakdown voltage around the trench can be improved. In addition, as the breakdown voltage is improved, the drift region can be increased in concentration, and the drift region can be reduced in resistance.

Non-Patent Document 1 discloses a technique in which a conventional trench gate structure (single gate structure) is arranged as an assist gate between trenches of a split gate structure, thereby increasing the density of gate electrodes in a cell region and reducing on-resistance. Such a power MOSFET is referred to as a split gate structure with an assist gate.

There are disclosed techniques listed below.
[Patent Document 1] Japanese Unexamined Patent Application Publication No. 2011-199109
[Non-Patent Document 1] W. Saito, et al., “Assist Gate MOSFETs for Improvement of On-Resistance and Turn-Off Loss Trade-Off”, IEEE ELECTRON DEVICE LETTERS, vol. 41, no. 7, pp. 1060-1062, July. 2020

### SUMMARY

In a MOSFET of the split gate structure with the assist gate, in order to reduce the on-resistance, the breakdown voltage must also be taken into account. That is, it is required not to destabilize the charge balance.

It is a primary purpose of the present application to optimize the planar layout of the split gate structure with an assist gate, thereby stabilizing the charge balance and improving the performance of the semiconductor device. Other objects and novel features will become apparent from the description of this specification and the accompanying drawings.

The typical ones of the embodiments disclosed in the present application will be briefly described as follows.

A semiconductor device according to one embodiment comprises: a semiconductor substrate of a first conductivity type having an upper surface and a lower surface; a first trench formed in the semiconductor substrate so as to reach a predetermined depth from the upper surface of the semiconductor substrate; a field plate electrode formed at a lower portion of the first trench inside the first trench and electrically isolated from the semiconductor substrate; a first gate electrode formed at an upper portion of the first trench inside the first trench and electrically isolated from the semiconductor substrate and the field plate electrode; a second trench formed in the semiconductor substrate so as to reach a predetermined depth from the upper surface of the semiconductor substrate; and a second gate electrode formed inside the second trench and electrically isolated from the semiconductor substrate. A depth of the first trench is greater than a depth of the second trench. The first trench extends in a first direction in plan view. The second trench extends in a second direction intersecting the first direction in plan view. The first trench and the second trench communicate with each other. The first gate electrode and the second gate electrode are integrated with each other.

A method of manufacturing a semiconductor device according to one embodiment comprises: (a) preparing a semiconductor substrate of a first conductivity type having an upper surface and a lower surface; (b) after (a), forming a first trench and a second trench in the semiconductor substrate so as to reach a predetermined depth from the upper surface of the semiconductor substrate; (c) after (b), selectively deepening the depth of the first trench so that the depth of the first trench becomes deeper than the depth of the second trench; (d) after (c), forming a first insulating film, on the upper surface of the semiconductor substrate, inside the first trench, and inside the second trench; (e) after (d), forming a first conductive film on the first insulating film so as to fill the inside of the first trench and the inside of the second trench; (f) after (e), removing the first conductive film located outside the first trench and outside the second trench to form the first conductive film left inside the first trench and inside the second trench as a field plate electrode; (g) after (f), removing the field plate electrode inside the second trench and retreating the field plate electrode inside the first trench toward the bottom of the first trench; (h) after (g), removing the first insulating film located on the upper surface of the semiconductor substrate and inside the second trench and retreating the first insulating film inside the first trench toward the bottom of the first trench so that the position of the upper surface of the first insulating film located inside the first trench is lower than the position of the upper surface of the field plate electrode; (i) after (h), selectively forming a second insulating film so as to cover the field plate electrode exposed from the first insulating film inside the first trench; (j) after (i), forming a first gate insulating film inside the first trench located on the second insulating film and forming a second gate insulating film inside the second trench; (k) after (j), forming a second conductive film on the first gate insulating film, on the second insulating film, and on the second gate insulating film so as to fill the inside of the first trench and the inside of the second trench; and (l) after (k), removing the second conductive film outside the first trench and outside the second trench to form the second conductive film left inside the first trench above the field plate electrode as a first gate electrode and form the second conductive film left inside the second trench as a second gate electrode. The first trench extends in a first direction in plan view. The second trench extends in a second direction intersecting the first direction in plan view. The first trench and the second trench communicate with each other. The first gate electrode and the second gate electrode are integrated with each other. According to one embodiment, the performance of a semiconductor device can be improved.

### BRIEF DESCRIPTION OF THE DRAWINGS

FIG. 1 is a plan view indicating the semiconductor device in the first embodiment.

FIG. 2 is a main portion perspective view of a semiconductor device in a the first embodiment.

FIG. 3 is a main portion plan view indicating the semiconductor device in the first embodiment.

FIG. 4 is a main portion plan view indicating the semiconductor device in the first embodiment.

FIG. 5 is a cross-sectional view indicating the semiconductor device in the first embodiment.

FIG. 6 is a cross-sectional view indicating the semiconductor device in the first embodiment.

FIG. 7 is a cross-sectional view indicating the semiconductor device in the first embodiment.

FIG. 8 is an equivalent circuit diagram showing a semiconductor device in the first embodiment.

FIG. 9 is a cross-sectional view showing the manufacturing process of the semiconductor device in the first embodiment.

FIG. 10 is a cross-sectional view illustrating a manufacturing process following FIG. 9.

FIG. 11 Fig. is a cross-sectional view illustrating a manufacturing step following FIG. 10.

FIG. 12 is a cross-sectional view illustrating a manufacturing process following FIG. 11.

FIG. 13 is a cross-sectional view illustrating a manufacturing process following FIG. 12.

FIG. 14 is a cross-sectional view illustrating a manufacturing process following FIG. 13.

FIG. 15 is a cross-sectional view illustrating a manufacturing process following FIG. 14.

FIG. 16 is a cross-sectional view illustrating a manufacturing step following FIG. 15.

FIG. 17 is a cross-sectional view illustrating a manufacturing step following FIG. 16.

FIG. 18 is a cross-sectional view illustrating a manufacturing step following FIG. 16.

FIG. 19 is a cross-sectional view showing a manufacturing process following FIGS. 17 and 18.

FIG. 20 is a cross-sectional view illustrating a manufacturing process following FIG. 19.

FIG. 21 is a cross-sectional view illustrating a manufacturing step following FIG. 20.

FIG. 22 is a cross-sectional view illustrating a manufacturing step following FIG. 21.

FIG. 23 is a cross-sectional view illustrating a manufacturing step following FIG. 22.

FIG. 24 is a cross-sectional view illustrating a manufacturing step following FIG. 23.

FIG. 25 is a cross-sectional view illustrating a manufacturing step following FIG. 24.

FIG. 26 is a cross-sectional view illustrating a manufacturing step following FIG. 25.

FIG. 27 is a cross-sectional view illustrating a manufacturing step following FIG. 26.

FIG. 28 is a cross-sectional view illustrating a manufacturing step following FIG. 27.

FIG. 29 is a cross-sectional view illustrating a manufacturing step following FIG. 28.

FIG. 30 is a main portion plan view indicating the semiconductor device in the first modified example.

FIG. 31 is a cross-sectional view showing the manufacturing process of the semiconductor device in the second modified example.

FIG. 32 is a cross-sectional view illustrating a manufacturing step following FIG. 31.

FIG. 33 is a cross-sectional view illustrating a manufacturing step following FIG. 32.

FIG. 34 is a cross-sectional view illustrating a manufacturing step following FIG. 33.

FIG. 35 is a cross-sectional view illustrating a manufacturing step following FIG. 34.

FIG. 36 is a main portion plan view indicating the semiconductor device in the third modified example.

FIG. 37 is a plan view indicating the semiconductor device in an examined example.

FIG. 38 is a main portion plan view indicating the semiconductor device in an examined example.

### DETAILED DESCRIPTION

In the following, embodiments will be described in detail based on drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In addition, the X direction, the Y direction, and the Z direction described in the present application intersect each other and are orthogonal to each other. In the present application, the Z direction is described as a vertical direction, depth, direction, a height direction, or a thickness direction of a certain structure. In addition, the expression “plan view” used in the present application means that the plane formed by the X direction and the Y direction is a “plane” and the “plane” is viewed from the Z direction.

### First Embodiment

### <Structure of Semiconductor Device>

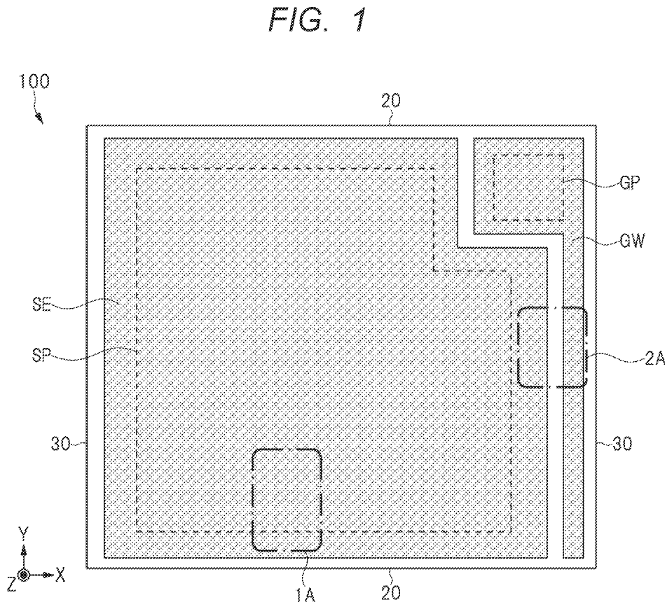

The semiconductor device 100 in the first embodiment will be described below with reference to FIGS. 1 to 8. The semiconductor device 100 includes a MOSFET of a split-gate structure with an assist gate as a semiconductor element. That is, in the semiconductor device 100, (i) a MOSFET of a split gate structure including a gate electrode GE1 and a field plate electrode formed inside the trench TR1 and (ii) a MOSFET of a single gate structure including a gate electrode GE2 formed inside the trench TR2 are connected in parallel.

FIG. 1 is plan view of a semiconductor-chip as the semiconductor device 100. In plan view, the majority of the semiconductor device 100 is covered with a source-electrode SE. Below the source-electrode SE is a cell region in which main semiconductor elements such as a MOSFET of a split gate structure with an assisted gate are formed. More specifically, the cell region is a region in which the source region NS is formed and is a region that can operate as a MOSFET. The semiconductor device 100 comprises a semiconductor substrate SUB, the semiconductor substrate SUB having an outer edge 20 along the X direction and an outer edge 30 along the Y direction. The gating wiring GW is formed along the outer edge 30 of the semiconductor substrate SUB.

Although not illustrated here, the source-electrode SE and the gate wiring GW are covered with a protective film such as a polyimide film. Openings are provided in a part of the protective film, and the source electrode SE and the gate wiring GW exposed in the openings become the source pad SP and the gate pad GP. External connecting members are connected to the source pad SP and the gate pad GP, respectively, so that the semiconductor device 100 is electrically connected to another semiconductor chip, a lead frame, a wiring substrate, or the like. The external connection member is, for example, a wire made of aluminum, gold, or copper, or a clip made of a copper plate.

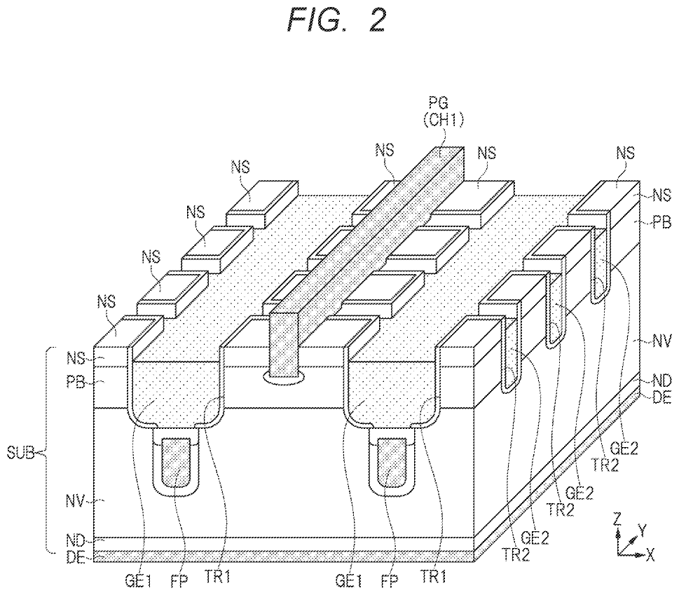

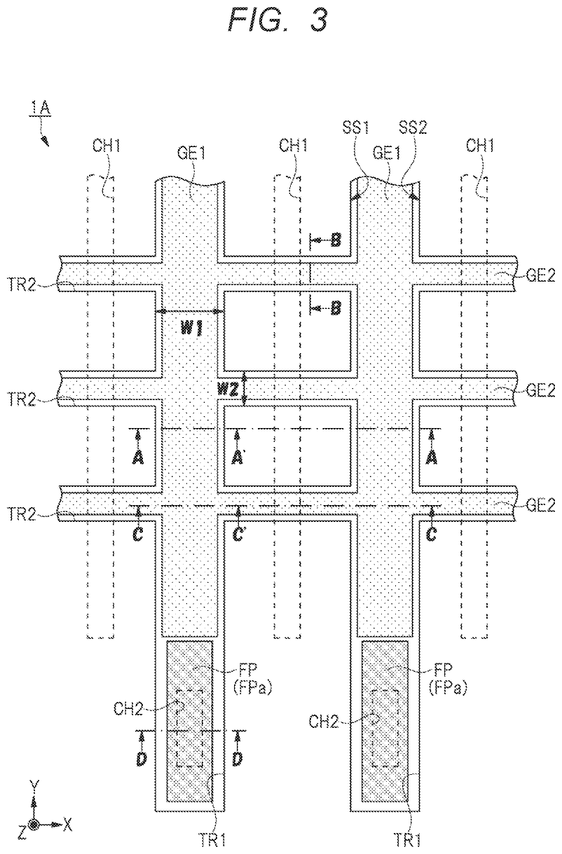

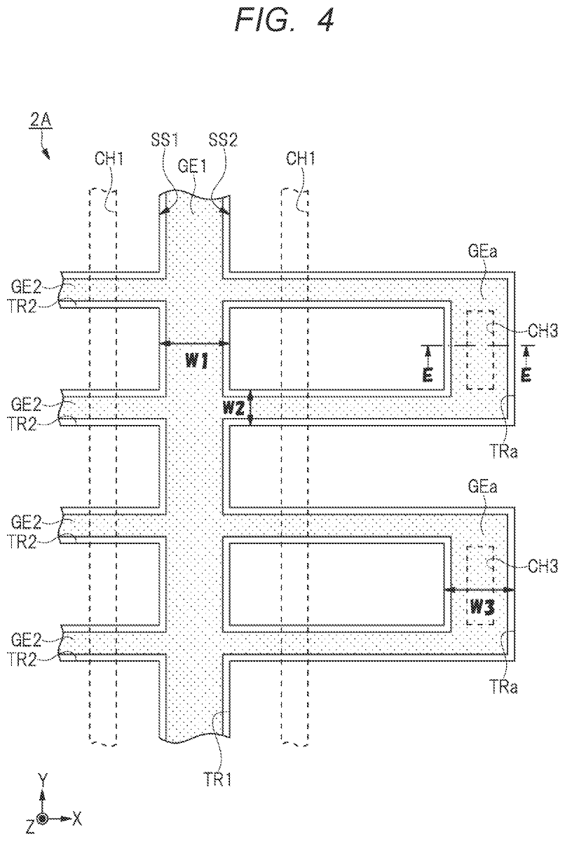

FIG. 2 is a perspective view illustrating an outline of a cell region in which a MOSFET of a split gate structure with an assist gate is formed. FIG. 3 is an enlarged main portion plan view of the region 1A shown in FIG. 1. FIG. 4 is an enlarged main portion plan view of the region 2A shown in FIG. 1.

FIG. 3 and FIG. 4 mainly show planar patterns of a trench TR1, a trench TR2, a gate electrode GE1, a gate electrode GE2, and a contact portion FPa (field plate electrode FP) formed in the semiconductor substrate SUB.

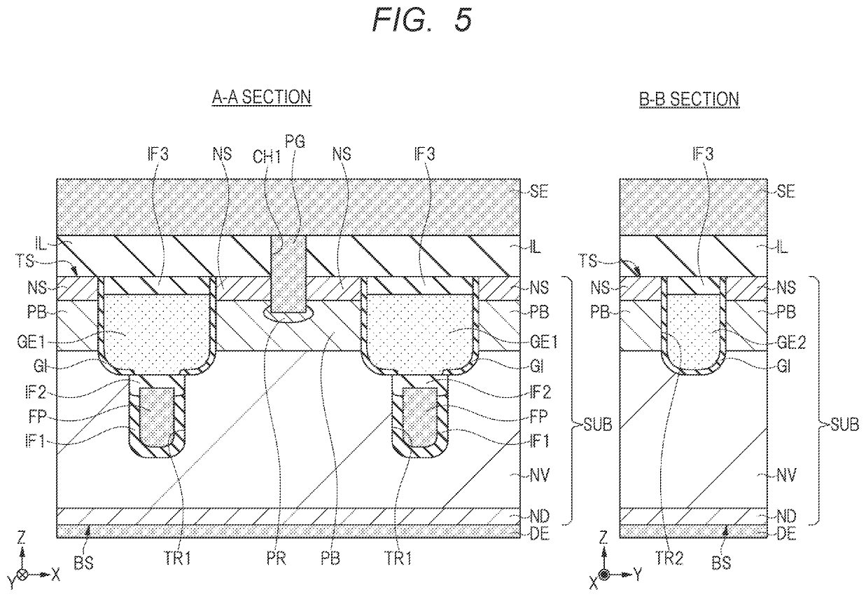

As shown in FIG. 3, a plurality of trenches TR1 is formed in the semiconductor substrate SUB. As shown in FIG. 3, the plurality of trenches TR1 is each formed in a stripe-like shape, extends in the Y direction, and adjoins each other in the X direction. As shown in FIG. 5 and the like, inside the trench TR1, a field plate electrode FP is formed at a lower portion of the trench TR1, and a gate electrode GE1 is formed at an upper portion of the trench TR1. The field plate electrode FP and the gate electrode GE1 extend in the Y-direction along the trench TR1.

A part of the field plate electrode FP forms a contact portion FPa. The field plate electrode FP constituting the contact portion FPa is formed not only in the lower portion of the trench TR1 but also in the upper portion of the trench TR1 inside the trench TR1.

The contact portion FPa is provided in a terminal portion of the trench TR1 in the Y-direction. That is, the contact portion FPa is provided near the outer edge 20 of the semiconductor substrate SUB.

A plurality of trenches TR2 is formed in the semiconductor substrate SUB. As shown in FIG. 3, the plurality of trenches TR2 is each formed in a stripe-like shape, extends in the X direction, and adjoins each other in the Y direction. A gate electrode GE2 is formed inside the trench TR2. The gate electrode GE2 extends in the Y-direction along the trench TR2.

The trench TR1 and the trench TR2 are in communication with each other and intersect each other. The gate electrode GE1 and the gate electrode GE2 are integrated and made of the same conductive film CF2 as described later.

The trench TR1 has a side surface SS1 and a side surface SS2 facing the side surface SS1 in the X-direction. In the first embodiment, a plurality of trenches TR2 formed in the semiconductor substrate SUB on the side surface SS1 side and a plurality of trenches TR2 formed in the semiconductor substrate SUB on the side surface SS2 side are arranged in line symmetry about the trench TR1 in plan view. That is, the plurality of trenches TR2 on the side surface SS1 side and the plurality of trenches TR2 on the side surface SS2 side are connected to each other in a straight line, respectively.

Each of the plurality of holes CH1 is formed in a stripe-like shape, extends in the Y-direction, and is provided so as to adjoin the trench TR1, respectively. One hole CH1 is provided between the two trenches TR1. A source potential is supplied from the source electrode SE to the source region NS and the body region PB via the hole CH1. Further, the hole CH1 intersects the trench TR2 in plan view, but as will be described later, since the hole CH1 does not reach the gate electrode GE2, the source potential is not supplied to the gate electrode GE2.

A hole CH2 is provided on the contact portion FPa of the field plate electrode FP. A source potential is supplied from the source electrode SE to the contact portion FPa and the field plate electrode FP via the hole CH2.

As shown in FIG. 4, the semiconductor substrate SUB near the outer edge 30 is provided with a lead-out trench TRa extending in the Y-direction. The lead-out trench TRa is provided so as to communicate with a terminal portion of the trench TR2 in the X-direction. Although FIG. 4 illustrates an example in which the lead-out trench TRa is in communication with two trenches TR2, the lead-out trench TRa may be in communication with a plurality of trenches TR2, such as three or more trenches TR2. Further, the lead-out trench TRa is formed in the same manufacturing process as the trench TR2, and has the same depth as the trench TR2.

A lead-out portion GEa is formed inside the lead-out trench TRa. The lead-out portion GEa and the gate electrode GE2 are integrated and are made of the same conductive film CF2 as described later.

A hole CH3 is provided on the lead-out portion GEa. Via the hole CH3, a gate potential is supplied from the gate wiring GW to the lead-out portion GEa, the gate electrode GE2, and the gate electrode GE1.

Further, the width W2 of the trench TR2 in the Y direction is narrower than the width W1 of the upper portion of the trench TR1 in the X direction. The width W3 of the lead-out trench TRa in the X-direction is wider than the width W2 of the trench TR2. Since the trench TR2 has a narrow width W2, it is difficult to form the hole CH3 on the gate electrode GE2. Therefore, for connecting with the hole CH3, a lead-out trench TRa having a wide width W3 is provided.

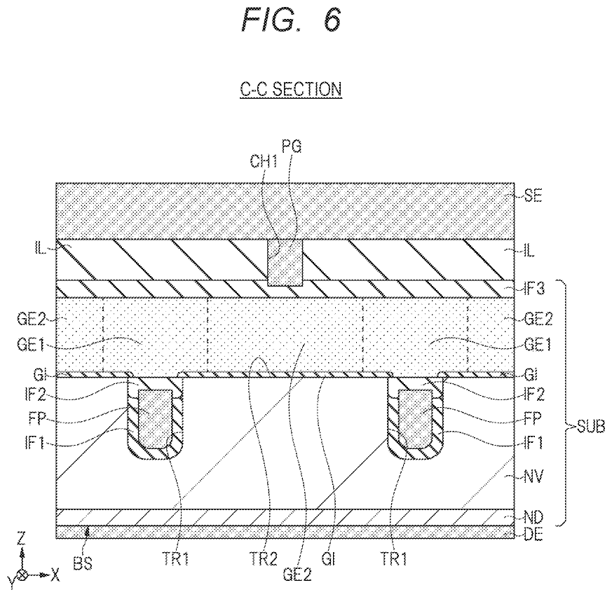

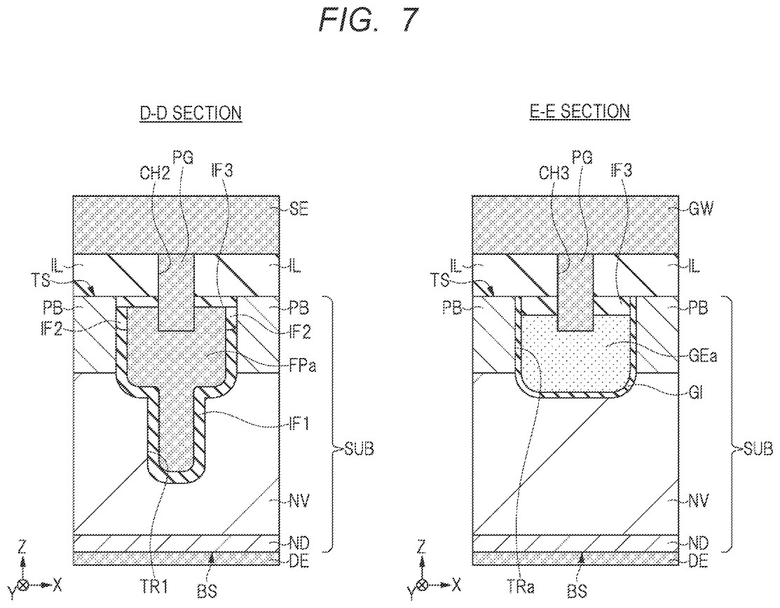

The cross-sectional configuration of the semiconductor device 100 will be described below with reference to FIGS. 5 to 7. FIG. 5 is a cross-sectional view along A-A and B-B lines shown in FIG. 3. FIG. 6 is a cross-sectional view along C-C shown in FIG. 3. FIG. 7 is a cross-sectional view along D-D line shown in FIG. 3 and a E-E line shown in FIG. 4. In the following description, FIG. 5 is mainly used, but FIG. 6 and FIG. 7 are used as necessary.

As shown in FIG. 5, the semiconductor device 100 comprises an n-type the semiconductor substrate SUB having an upper surface TS and a bottom surface BS. The semiconductor substrate SUB is made of n-type silicon. The semiconductor substrate SUB has a low concentration n-type drift region NV. In the first embodiment, the n-type semiconductor substrate SUB itself constitutes the drift-region NV. The semiconductor substrate SUB may be a laminate of an n-type silicon substrate and an n-type semiconductor layer grown on the silicon substrate while introducing phosphorus (P) by an epitaxial growth method. In that case, a low-concentration n-type semiconductor layer constitutes the drift region NV, and a high-concentration n-type silicon substrate constitutes the drain region ND.

As shown in FIG. 5, an n-type drain-region ND is formed closer to the lower surface BS than to the upper surface TS of the semiconductor substrate SUB. The drain region ND has a higher impurity concentration than the drift region NV. A drain-electrode DE is formed below the lower surface BS of the semiconductor substrate SUB. The drain electrode DE consists of a single layer of a metallic membrane, such as an aluminum membrane, a titanium membrane, a nickel membrane, a gold membrane or a silver membrane, or a laminated membrane with these metallic membranes laminated accordingly. The drain region ND and the drain electrode DE are formed over the entire lower surface BS of the semiconductor substrate SUB. The drain potential is supplied to the semiconductor substrate SUB (drain region ND, drift region NV) from the drain electrode DE.

As shown in A-A cross section of FIG. 5, a trench TR1 that reaches a predetermined depth from the upper surface TS of the semiconductor substrate SUB is formed in the semiconductor substrate SUB. The depth of the trench TR1 is, for example, 5 μm (micrometers) or more and 7 μm (micrometers) or less. Inside the trench TR1, a field plate electrode FP is formed at a lower portion of the trench TR1 via an insulating film IF1. Inside the trench TR1, a gate electrode GE1 is formed at an upper portion of the trench TR1 via a gate insulating film GI. Each of the field plate electrode FP and the gate electrode GE1 is formed of, for example, an n-type doped polycrystalline silicon film.

Due to the manufacturing process described later, the width of the lower portion of the trench TR1 is narrower than the upper portion of the trench TR1.

The position of the upper surface of the insulating film IF1 is lower than the position of the upper surface of the field plate electrode FP. An insulating film IF2 is formed so as to cover the field plate electrode FP exposed from the insulating film IF1. The gate insulating film GI is formed inside the trench TR1 on the insulating film IF2. The position of the upper surface of the gate electrode GE1 is lower than the upper surface TS of the semiconductor substrate SUB. An insulating film IF3 is formed on the gate electrode GE1.

The insulating film IF1 is formed between the semiconductor substrate SUB and the field plate electrode FP. The insulating film IF2 is formed between the gate electrode GE1 and the field plate electrode FP. The gate insulating film GI is formed between the semiconductor substrate SUB and the gate electrode GE1. With these films, the semiconductor substrate SUB, the gate electrode GE1, and the field plate electrode FP are electrically insulated from each other.

The insulating film IF1, the insulating film IF2, and the gate insulating film GI are made of, for example, a silicon-oxide film. The thickness of the insulating film IF1 is larger than the thickness of the gate insulating film GI. Inside the trench TR1, the thickness of the insulating film IF1 is, for example, 400 nm or more and 600 nm or less. In the trench TR1, the thickness of the gate insulating film GI is, for example, equal to or greater than 50 nm and equal to or less than 70 nm. The insulating film IF3 is formed of, for example, a silicon oxide film or a silicon nitride film.

As shown in B-B cross section of FIG. 5, a trench TR2 that reaches a predetermined depth from the upper surface TS of the semiconductor substrate SUB is formed in the semiconductor substrate SUB. The depth of the trench TR2 is, shallower than the depth of the trench TR1, for example, 2 μm (micrometers) or more and 3 μm (micrometers) or less. A gate electrode GE2 is formed inside the trench TR2 via a gate insulating film GI. An electrode other than the gate electrode GE2 is not formed inside the trench TR2. The semiconductor substrate SUB and the gate electrode GE2 are electrically insulated from each other by the gate insulating film GI. The gate electrode GE2 is formed of, for example, an n-type doped polycrystalline silicon film. The position of the upper surface of the gate electrode GE2 is lower than the upper surface TS of the semiconductor substrate SUB. An insulating film IF3 is formed on the gate electrode GE2.

A p-type body region PB is formed closer to the upper surface TS than to the lower surface BS of the semiconductor substrate SUB. The depth of the body region PB from the upper surface TS of the semiconductor substrate SUB is shallower than the depth of each of the trench TR1 and the trench TR2. In the body region PB, an n-type source region NS is formed. The source region NS has a higher impurity concentration than the drift region NV.

An interlayer insulating film IL is formed on the upper surface TS of the semiconductor substrate SUB so as to cover the trench TR1 and the trench TR2. The interlayer insulating film IL is formed of, for example, a silicon oxide film. The thickness of the interlayer insulating film IL is, for example, 500 nm or more and 900 nm or less.

A hole CH1 is formed in the interlayer insulating film IL. The hole CH1 reaches the source region NS and the body region PB. At the bottom of the hole CH1, a high concentration diffusion region PR is formed in the body region PB. The high concentration diffusion region PR is formed mainly in order to reduce the contact resistance with the plug PG and has a higher impurity concentration than the body region PB.

A plug PG is formed inside the hole CH1. The plug PG includes, for example, a first barrier metal film and a first conductive film formed on the first barrier metal film. The first barrier metal film is formed of, for example, a laminated film of a titanium film and a titanium nitride film. The first conductive film is, for example, a tungsten film.

A source-electrode SE is formed on the interlayer insulating film IL. The source electrode SE is electrically connected to the source region NS, the body region PB, and the high concentration diffusion region PR via the hole CH1 (plug PG).

As shown in FIGS. 2 and 3, the hole CH1 intersects the trench TR2 in plan view. However, as shown in C-C cross section of FIG. 6, the bottom of the hole CH1 is located on the insulating film IF3 and does not reach the gate electrode GE2. Therefore, the gate electrode GE2 is not electrically connected to the source-electrode SE.

As shown in D-D cross section of FIG. 7, a hole CH2 is formed in the interlayer insulating film IL. The hole CH2 goes through the insulating film IF3 and reaches the contact portion FPa of the field plate electrode FP. A plug PG is also formed inside the hole CH2. The source electrode SE is electrically connected to the contact portion FPa via the hole CH2 (plug PG).

As shown in E-E cross-section of FIG. 7, a lead-out trench TRa that reaches a predetermined depth from the upper surface TS of the semiconductor substrate SUB is formed in the semiconductor substrate SUB. The trench TR2 and the lead-out trench TRa are in communication. A lead-out portion GEa integrated with the gate electrode GE2 is formed inside the lead-out trench TRa.

A hole CH3 is formed in the interlayer insulating film IL. The hole CH3 goes through the insulating film IF3 and reaches the lead-out portion GEa. A plug PG is also formed inside the hole CH3. A gate wiring GW is formed on the interlayer insulating film IL. The gate wiring GW is electrically connected to the lead-out portion GEa via the hole CH3 (plug PG).

The source-electrode SE and the gate wiring GW include, for example, a second barrier metal film and a second conductive film formed on the second barrier metal film. The second barrier metal film is, for example, a titanium tungsten film. The second conductive film is, for example, an aluminum alloy film to which copper or silicon is added.

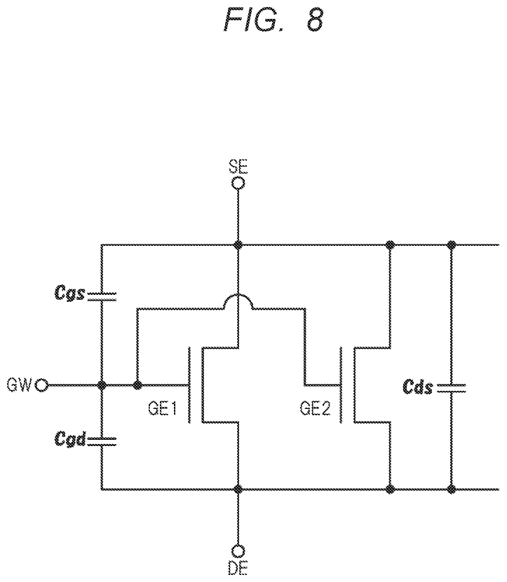

FIG. 8 is an equivalent circuit diagram of a MOSFET of a split gate structure with an assist gate in the first embodiment. A MOSFET of a split gate structure including a gate electrode GE1 and a field plate electrode FP and a MOSFET of a single gate structure including a gate electrode GE2 are connected in parallel.

Note that the capacitance Cgs shown in FIG. 8 is the sum of the capacitance between the gate electrode GE1 and the field plate electrode FP, the capacitance between the gate electrode GE1 and the base region PB, and the capacitance between the gate electrode GE2 and the base region PB. The capacitance Cgd is the sum of the capacitance between the gate electrode GE1 and the drift region NV and the capacitance between the gate electrode GE2 and the drift region NV. The capacitance Cds is the sum of the capacitance between the source region NS and the drift region NV and the capacitance between the field plate electrode FP and the drift region NV.

### <Semiconductor Device of Examined Example, and Main Features of First Embodiment>

As described above, according to the first embodiment, the body region PB in contact with the side surface of the trench TR1 can be utilized as a channel region of a MOSFET of the split gate structure, and the body region PB in contact with the side surface of the trench TR2 can be utilized as a channel region of a MOSFET of the single gate structure. Therefore, the on-resistance can be further reduced as compared with the case of only MOSFET of the split-gate structure.

In addition, since the trench TR1 has a stripe-like shape, the depletion layer extending from the field plate electrode FP easily spreads evenly in the cell region, and the breakdown voltage can be secured. Therefore, the charge balance does not become unstable. In other words, according to the first embodiment, since the charge balance is stabilized, the on-resistance can be reduced and the breakdown voltage can be secured at the same time, and the performance of the semiconductor device 100 can be improved.

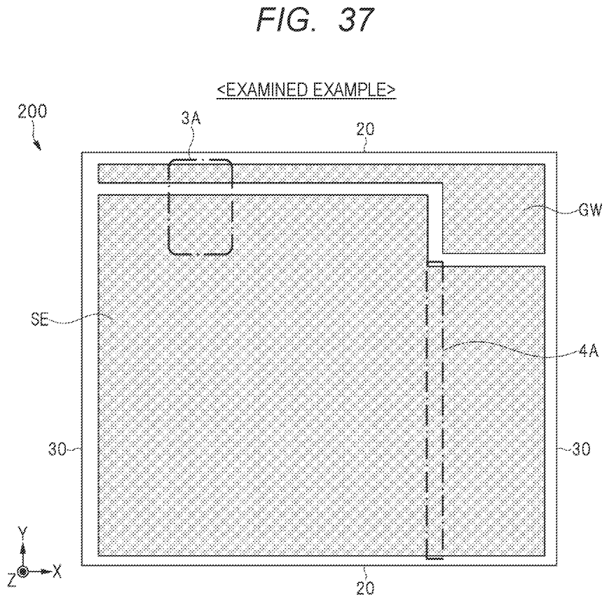

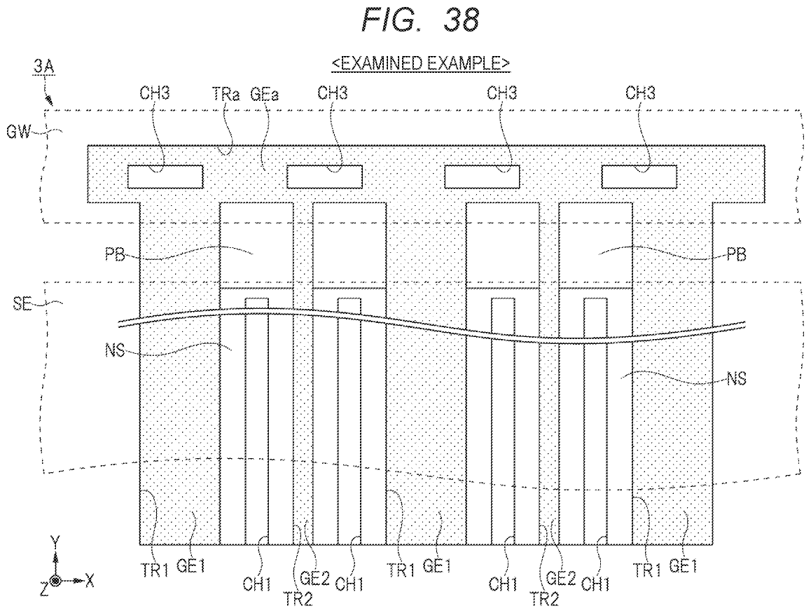

A semiconductor device in an examined example will be described below with reference to FIG. 37 and FIG. 38. FIG. 38 is an enlarged main portion plan view of the region 3A shown in FIG. 37.

As shown in FIG. 37, in the examined example, a gate wiring GW is formed along the outer edge 20 of the semiconductor substrate SUB. As shown in FIG. 38, in the examined example, the trench TR1 and the trench TR2 are formed in a stripe-like shape, extend in the Y direction, respectively, and adjoin each other in the X direction. The lead-out trench TRa extends in the X-direction along the outer edge 20 and communicates with each of the trench TR1 and the trench TR2. A lead-out portion GEa integrated with each of the gate electrode GE1 and the gate electrode GE2 is formed inside the lead-out trench TRa.

Even in the examined example, it is possible to realize a MOSFET of the split gate structure with an assist gate, and it is possible to stabilize the charge balance in which the on-resistance is reduced and the breakdown voltage is secured.

However, in the examined example, since the trench TR2 extending in the same direction as the trench TR1 is provided between two trenches TR1, it is difficult to further reduce the on-resistance while securing the breakdown voltage as compared with the first embodiment.

For example, in order to promote reduction of the on-resistance, the distance between the two trench TR1 is increased when a plurality of trenches TR2 are provided between the two trenches TR1. In this case, a region where a depletion layer from the field plate electrode FP does not reach is likely to occur, and it becomes difficult to secure the breakdown voltage. In other words, further reduction of the on-resistance is limited by the distance between the respective trenches TR1 in the X-direction.

In contrast, in the first embodiment, the trench TR1 and the trench TR2 extend in different directions, so that the arrangement of the trench TR2 is not constrained by the distances between the respective trenches TR1 in the X direction. The number of the trenches TR2 can be increased with the distance between the respective trenches TR1 being the minimum distance enabling to secure the breakdown voltage. As the number of the trenches TR2 increases, the current density increases, and the on-resistance can be reduced. Therefore, it is possible to further reduce the on-resistance while securing the breakdown voltage, and thus it is possible to improve the performance of the semiconductor device 100.

Further, in order to increase the number of trenches TR2, it is effective to make the width W2 of the trench TR2 and the distance between the respective trenches TR2 as narrow as possible. This makes it difficult to form a hole CH3 on the gate electrode GE2, but for connecting to the hole CH3, a lead-out trench TRa having a wide width W3 and a lead-out portion GEa inside of it are provided (see FIG. 4). Therefore, the gate potential can be supplied to the gate electrode GE2 and the gate electrode GE1 while effectively reducing the on-resistance.

In addition, a design concept is possible in which, in terms of securing the breakdown voltage, it is adjusted by the distance between the respective trenches TR1, and in terms of reducing the on-resistance, it is adjusted by the number of the trenches TR2. Since securing the breakdown voltage and reducing the on-resistance are considered separately, it can be said that the semiconductor device 100 of the first embodiment is a device that is easier to design.

Further, in the examined example, since the extending directions of the trench TR1 and the trench TR2 are the same, the contact portion FPa of the field plate electrode FP needs to be provided on one outer edge 20 side (see FIG. 3), and the lead-out trench TRa and the lead-out portion GEa need to be provided on the other outer edge 20 side. Therefore, as shown in FIG. 37, there is an invalid region 4A. The invalid region 4A is a region where it is difficult to arrange a MOSFET.

That is, there is a gap between the gate wiring GW and the source electrode SE in the X-direction. When the trench TR1 or the trench TR2 is formed from the gap toward the Y-direction, the gate electrode GE1 or the gate electrode GE2 cannot be electrically connected to the gate wiring GW. Therefore, since a MOSFET cannot be formed in the invalid region 4A, the arrangement density of MOSFET in the entire semiconductor device 100 is reduced.

In contrast, in the first embodiment, the trench TR1 and the trench TR2 extending in directions different from each other communicate with each other, and the gate electrode GE1 and the gate electrode GE2 are integrated with each other. Therefore, as shown in FIGS. 1, 3, and 4, even when the contact portion FPa is provided on one outer edge 20 side, a gate potential can be supplied to the gate electrode GE2 and the gate electrode GE1 from the gate wiring GW via the lead-out portion GEa by providing the lead-out trench TRa and the lead-out portion GEa on the outer edge 30 side. Therefore, since the invalid region 4A such as in the examined example does not occur, it is possible to suppress a decrease in the arrangement density of MOSFET and to reduce the on-resistance.

Like the trench TR1, a field plate electrode FP may be formed inside the trench TR2. However, the trench in which the field plate electrode FP is embedded serves to maintain the breakdown voltage. Therefore, from the viewpoint of maintaining the breakdown voltage, the trench needs to be wider than the trench in which only the gate electrode GE2 is embedded. Accordingly, since the number of trenches that can be arranged is reduced, it is difficult to reduce the on-resistance. Therefore, it is preferable that an electrode other than the gate electrode GE2 is not formed inside the trench TR2.

### <Manufacturing Method of Semiconductor Device>

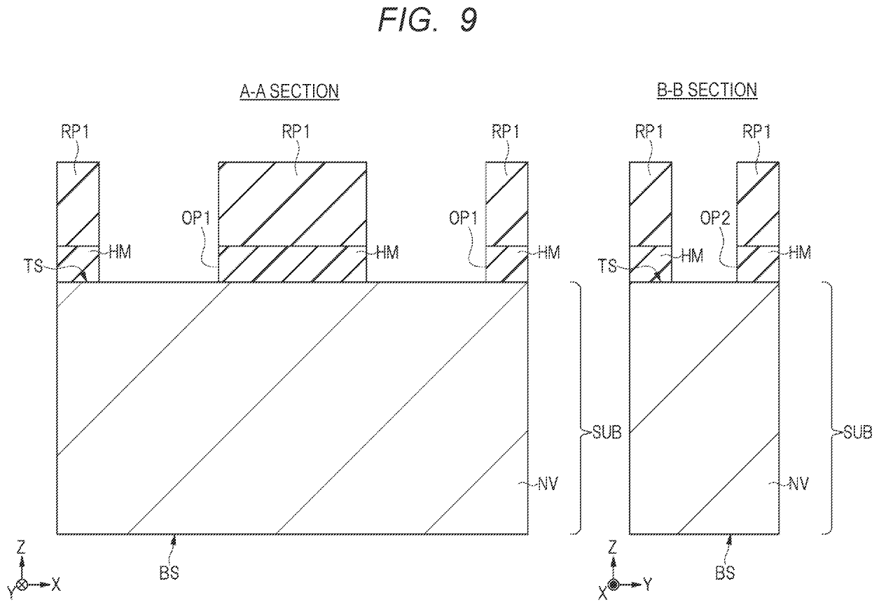

The respective manufacturing steps included in the manufacturing method of the semiconductor device 100 will be described below with reference to FIG. 9 to FIG. 29. In the following explanation, A-A cross section and B-B cross section of FIG. 5 are mainly used.

As shown in FIG. 9, first, an n-type semiconductor substrate SUB having a upper surface TS and a lower surface BS is prepared. As mentioned above, the semiconductor substrate SUB may be a stack of an n-type silicon substrate and n-type semiconducting layer formed on the silicon substrate by epitaxial growth.

Next, a hard mask HM made of, for example, a silicon nitride film is formed on the upper surface TS of the semiconductor substrate SUB by, for example, CVD (Chemical Vapor Deposition). Next, a resist pattern RP1 is selectively formed on the hard mask HM. Next, an anisotropic etch process is performed using the resist pattern RP1 as a mask to form an opening OP1 and an opening OP2 in the hard mask HM. Thereafter, the resist pattern RP1 is removed by an ashing process. In this way, a hard mask HM can be selectively formed on the upper surface TS of the semiconductor substrate SUB.

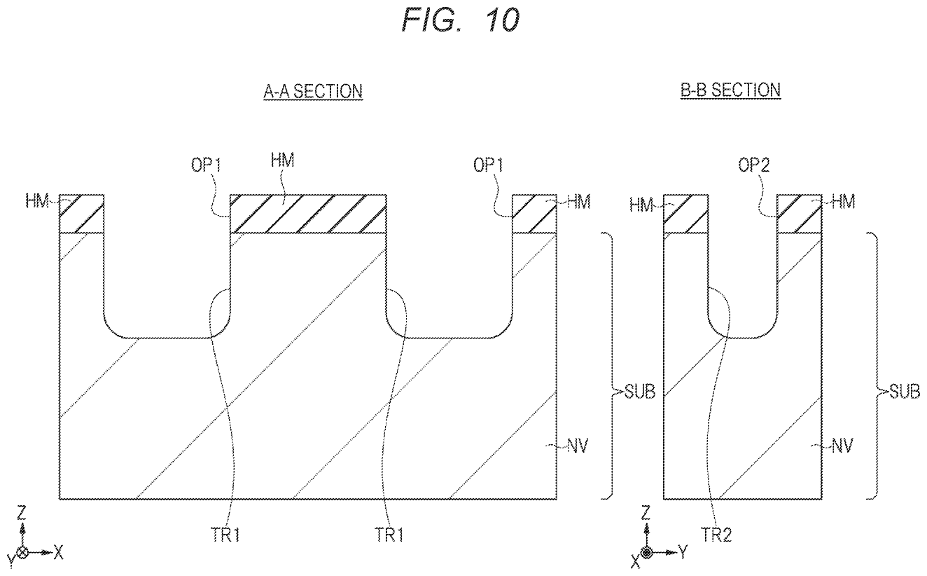

As shown in FIG. 10, an anisotropic etch process is performed using the hard mask HM as a mask, so that a trench TR1 and a trench TR2 are formed in the semiconductor substrate SUB exposed from the hard mask HM so as to reach a predetermined depth from the upper surface TS of the semiconductor substrate SUB. That is, in the semiconductor substrate SUB exposed at the opening OP1, a trench TR1 is formed, and in the semiconductor substrate SUB exposed at the opening OP2, a trench TR2 is formed. Note that the lead-out trench TRa is also formed by the manufacturing processes described above.

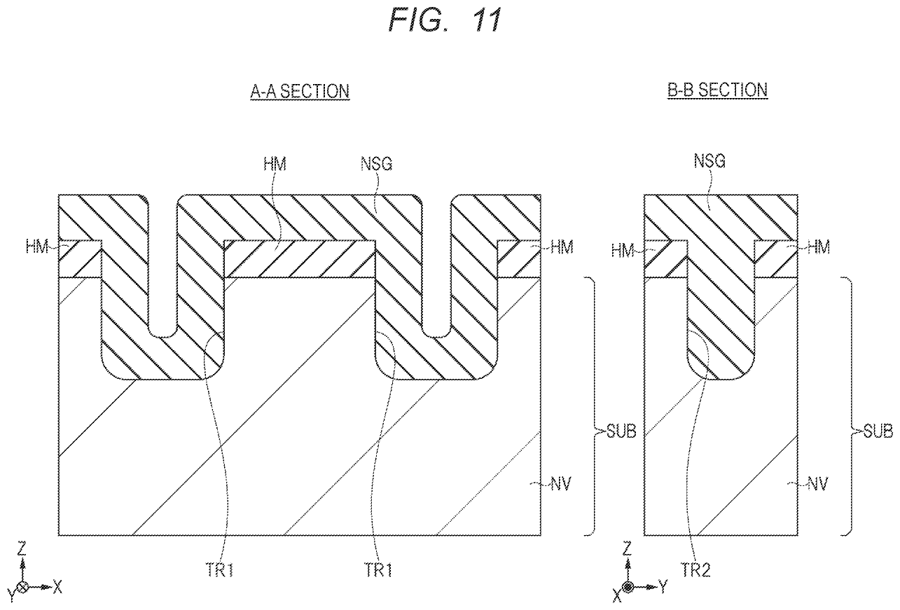

Next, the depth of the trench TR1 is selectively made deeper so that the depth of the trench TR1 becomes deeper than the depth of the trench TR2 by the manufacturing process described with reference to FIGS. 11 to 14.

As shown in FIG. 11, first, an insulating film NSG is formed inside of the trench TR1 and inside of the trench TR2 on the hard mask HM so that the inside of the trench TR1 is not completely filled and the inside of the trench TR2 is completely filled. Even when the insulating film NSG is completely embedded in the trench TR2, a certain amount of gap is generated in the trench TR1 because the width W1 of the trench TR1 is wider than the width W2 of the trench TR2 (see FIG. 3). Note that the insulating film NSG is a film of a material other than the hard mask HM, is a silicon oxide film, and is, for example, a non-doped silica glass.

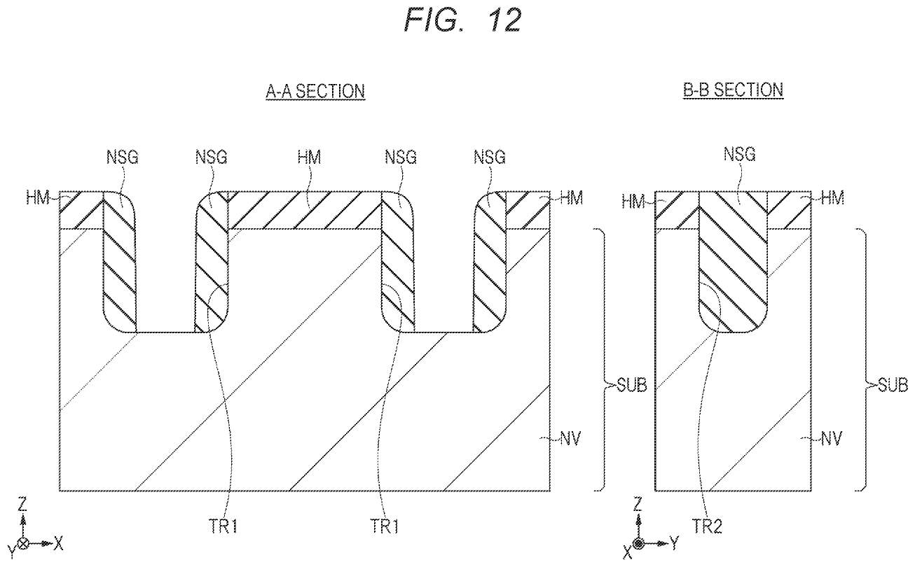

As shown in FIG. 12, the insulating film NSG is subjected to an anisotropic etch process. The anisotropic etching process is performed in such a condition that the insulating film NSG is easily etched and the hard mask HM is hardly etched. By this anisotropic etching process, the insulating film NSG on the hard mask HM is removed, and the insulating film NSG inside the trench TR1 is processed into a sidewall shape, leaving the insulating film NSG inside the trench TR2. In the trench TR2, the position of the upper surface of the insulating film NSG is higher than the position of the upper surface TS of the semiconductor substrate SUB.

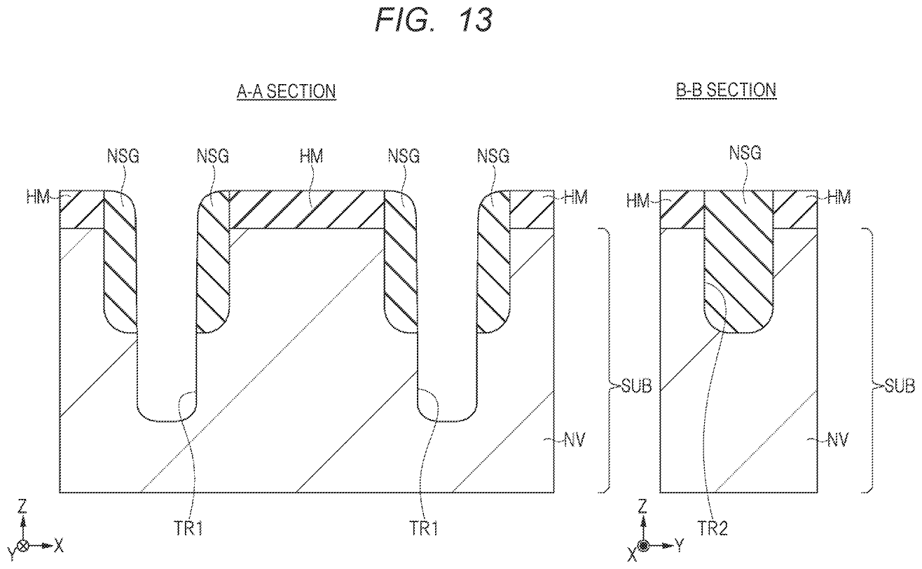

As shown in FIG. 13, an anisotropic etch process is performed using the hard mask HM and the insulating film NSG as masks. The anisotropic etching process is performed in such a condition that the semiconductor substrate SUB is easily etched and the hard mask HM and the insulating film NSG are hardly etched. This anisotropic etch process increases the depth of the trench TR1.

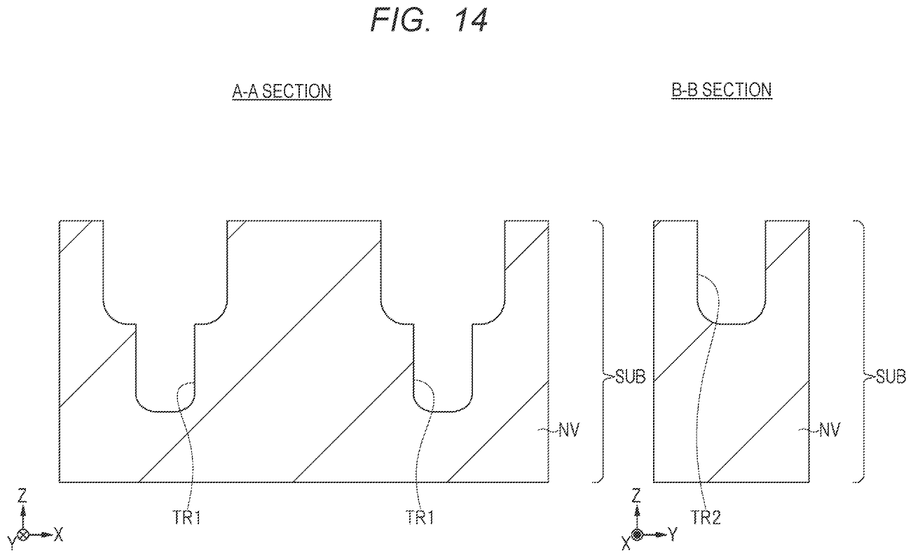

As shown in FIG. 14, the insulating film NSG and the hard mask HM are sequentially removed. The insulating film NSG can be removed by an isotropic etch process using, for example, a solution containing hydrofluoric acid. The hard mask HM can be removed by an isotropic etch process using, for example, a solution containing phosphoric acid.

As described above, in the manufacturing process for selectively increasing the depth of the trench TR1, it is possible to self-align using the hard mask HM and the insulating film NSG without using the resist pattern. Therefore, the cross-sectional shape of the trench TR1 can be accurately maintained without misalignment of the resist pattern.

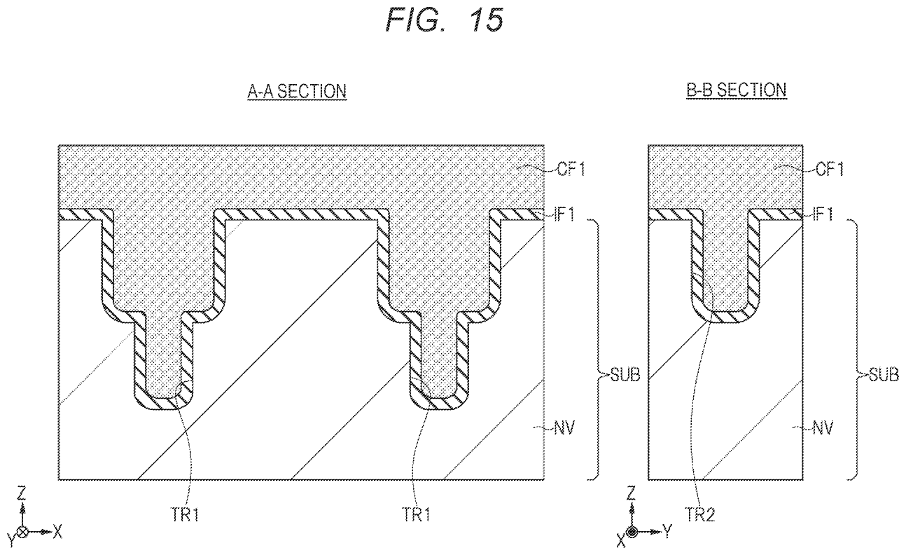

As shown in FIG. 15, an insulating film IF1 and a conductive film CF1 are formed inside the trench TR1 and inside the trench TR2.

First, an insulating film IF1 is formed on the upper surface TS of the semiconductor substrate SUB, inside the trench TR1, and inside the trench TR2 by, for example, thermal oxidation treatment. The insulating film IF1 may be a stacked film of a first silicon oxide film formed by thermal oxidation treatment and a second silicon oxide film formed by CVD on the first silicon oxide film.

Next, a conductive film CF1 is formed on the insulating film IF1 by, for example, a CVD method so as to fill the inside of the trench TR1 and the inside of the trench TR2. The conductive film CF1 is, for example, an n-type polycrystalline silicon film. In order to satisfactorily fill the conductive film CF1, the conductive film CF1 may be formed a plurality of times (for example, two times of forming as forming of the first polycrystalline silicon film and forming of the second polycrystalline silicon film).

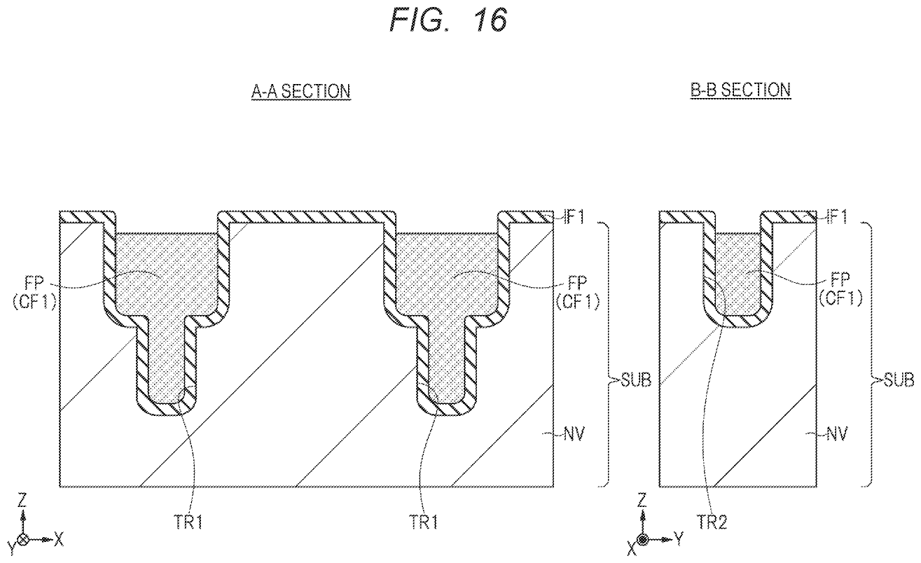

As shown in FIG. 16, a field plate electrode FP is formed inside the trench TR1 and inside the trench TR2.

First, the conductive film CF1 located outside the trench TR1 and outside the trench TR2 is removed by a polishing process using, for example, CMP (Chemical Mechanical Polishing). Next, the position of the upper surface of the conductive film CF1 is retracted by performing an anisotropic etch process. Accordingly, the conductive film CF1 left in the trench TR1 and in the trench TR2 is formed as the field plate electrode FP.

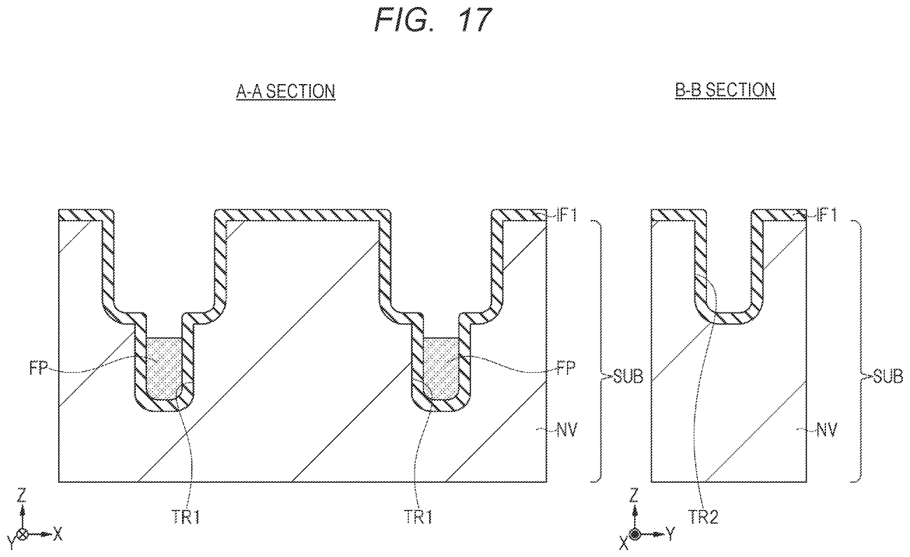

As shown in FIG. 17, the field plate electrode FP inside the trench TR2 is removed and the field plate electrode FP inside the trench TR1 is retracted.

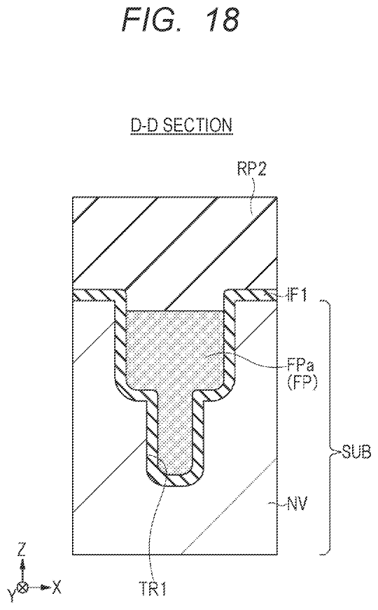

First, a resist pattern RP2 is formed on a part of the field plate electrode FP inside the trench R1, as shown in FIG. 18 (D-D cross-section). At this time, in A-A cross section and B-B cross section of FIG. 17, the field plate electrode FP is exposed from the resist pattern RP2.

Next, as shown in FIG. 17, an anisotropic etch process is performed using the resist pattern RP2 as a mask to remove the field plate FP inside the trench TR2. At the same time, the other part of the field plate electrode FP inside the trench TR1 is retracted toward the bottom of the trench TR1 so that a part of the field plate electrode FP inside the trench TR1 is left as a contact part FPa. Thereafter, the resist pattern RP2 is removed by an ashing process.

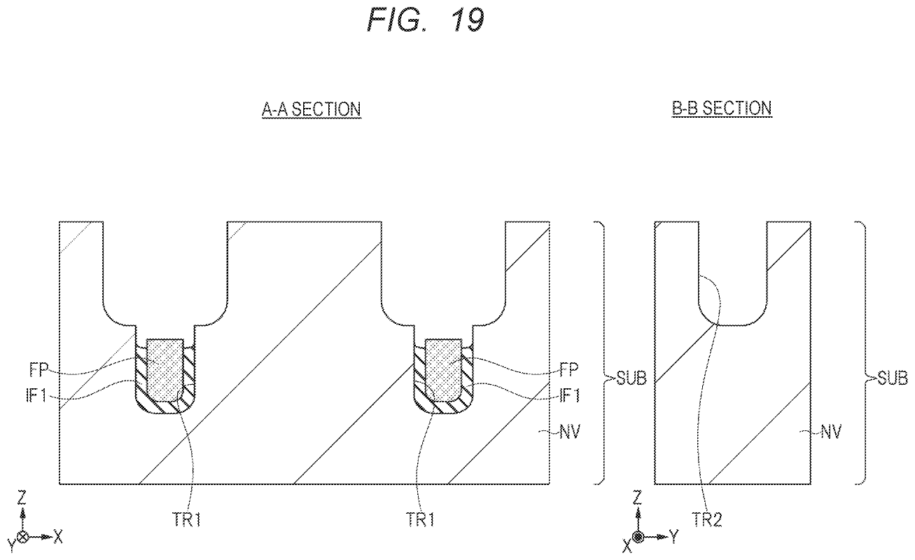

As shown in FIG. 19, the insulating film IF1 is subjected to an isotropic etch process using a solution containing hydrofluoric acid. Thus, the insulating film IF1 located on the upper surface TS of the semiconductor substrate SUB and the insulating film IF1 located inside the trench TR2 are removed. At the same time, the insulating film IF1 located inside the trench TR1 is retracted toward the bottom of the trench TR1 so that the position of the upper surface of the insulating film IF1 located inside the trench TR1 is lower than the position of the upper surface of the field plate electrode FP.

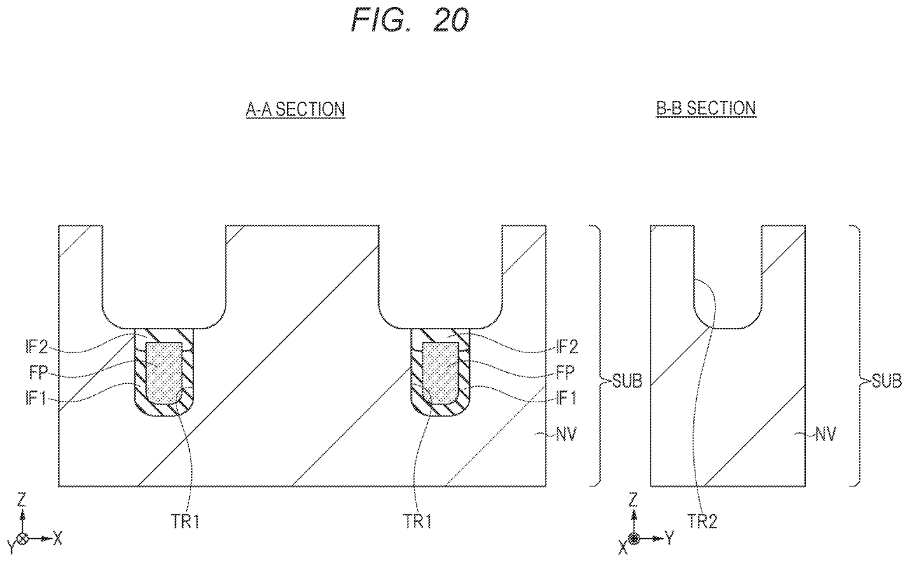

As shown in FIG. 20, an insulating film IF2 is selectively formed in the trench TR1 so as to cover the field plate electrode FP exposed from the insulating film IF1.

First, an insulating film IF2 is formed on the upper surface TS of the semiconductor substrate SUB, inside the trench TR1, and inside the trench TR2 by, for example, a CVD method. Next, an anisotropic etch process is performed on the insulating film IF2 to remove the insulating film IF2 located on the upper surface TS of the semiconductor substrate SUB and the insulating film IF2 located inside the trench TR2. At the same time, the insulating film IF2 located inside the trench TR1 is retracted toward the bottom of the trench TR1. As a result, the field plate electrode FP is covered with the insulating film IF2 left in the trench TR1.

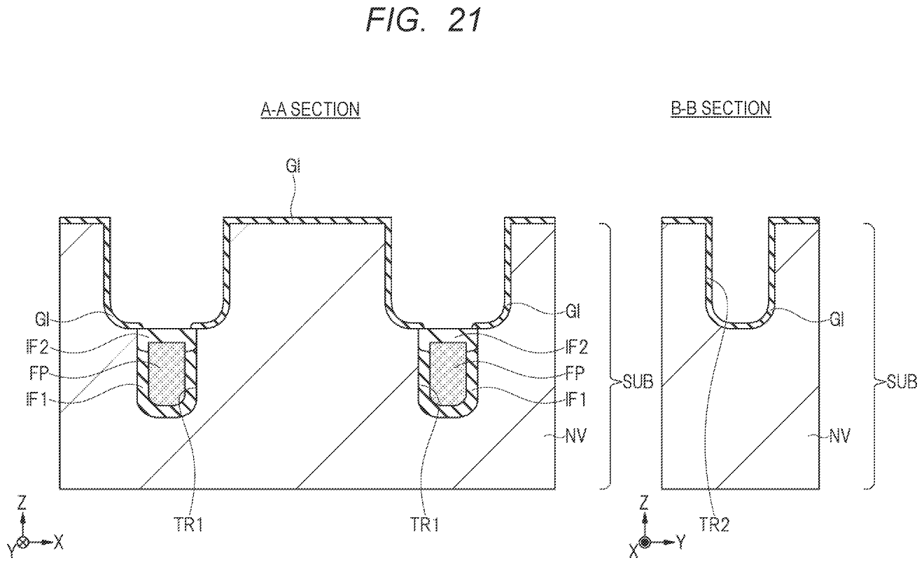

As shown in FIG. 21, a gate insulating film GI is formed on the upper surface TS of the semiconductor substrate SUB, and on the insulating film IF2 inside the trench TR1 and inside the trench TR2 by, for example, a thermal oxidization treatment. A gate insulating film GI is also formed inside the lead-out trench TRa.

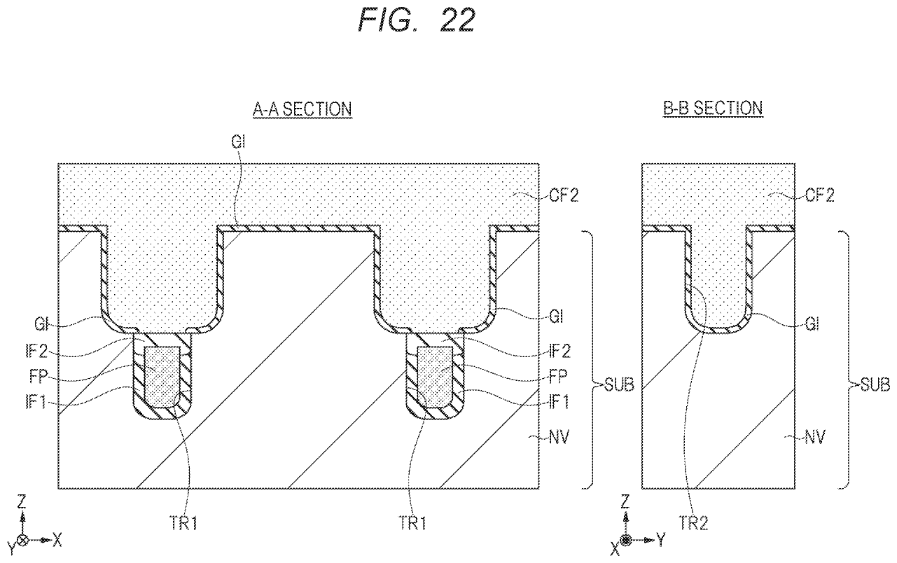

Next, as shown in FIG. 22, a conductive film CF2 is formed on the gate insulating film GI and the insulating film IF2 by, for example, a CVD method so as to fill the inside of the trench TR1 and the inside of the trench TR2. The conductive film CF2 is, for example, an n-type polycrystalline silicon film.

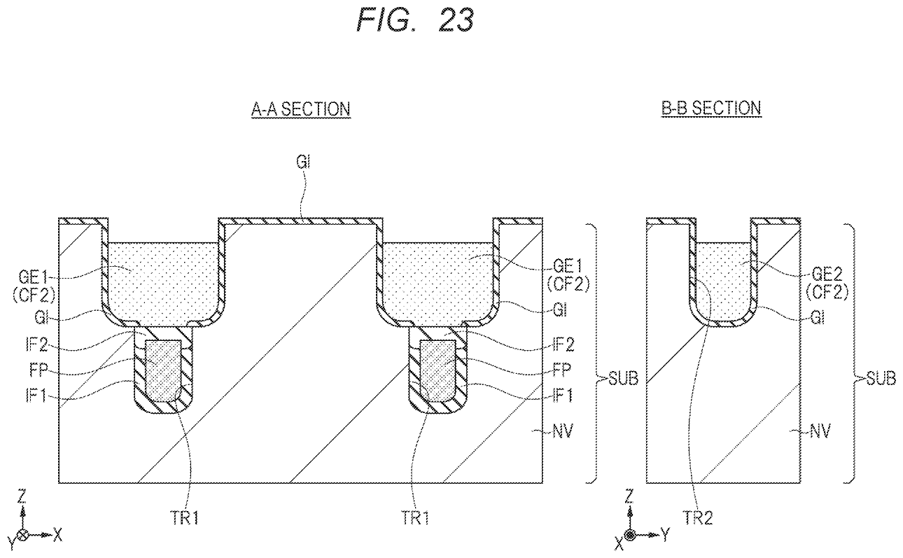

As shown in FIG. 23, a gate electrode GE1 is formed inside the trench TR1, and a gate electrode GE2 is formed inside the trench TR2.

First, a polishing treatment using a CMP method is performed on the conductive film CF2 by, for example, a polishing treatment using a CMP method. As a result, the thickness of the conductive film CF2 is reduced, and the upper surface of the conductive film CF2 is planarized.

Next, the conductive film CF2 is subject to an anisotropic etching to remove the conductive film CF2 located outside the trench TR1 and located outside the trench TR2. Accordingly, the conductive film CF2 left on the field plate electrode FP in the trench TR1 is formed as the gate electrode GE1. At the same time, the conductive film CF2 left in the trench TR2 is formed as the gate electrode GE2. Note that a lead-out portion GEa made of the conductive film CF2 is also formed inside the lead-out trench TRa.

Further, by continuing the anisotropic etch process, the gate electrode GE1 and the gate electrode GE2 are retracted so that the position of the upper surface of each of the gate electrode GE1 and the gate electrode GE2 is lower than the position of the upper surface TS of the semiconductor substrate SUB.

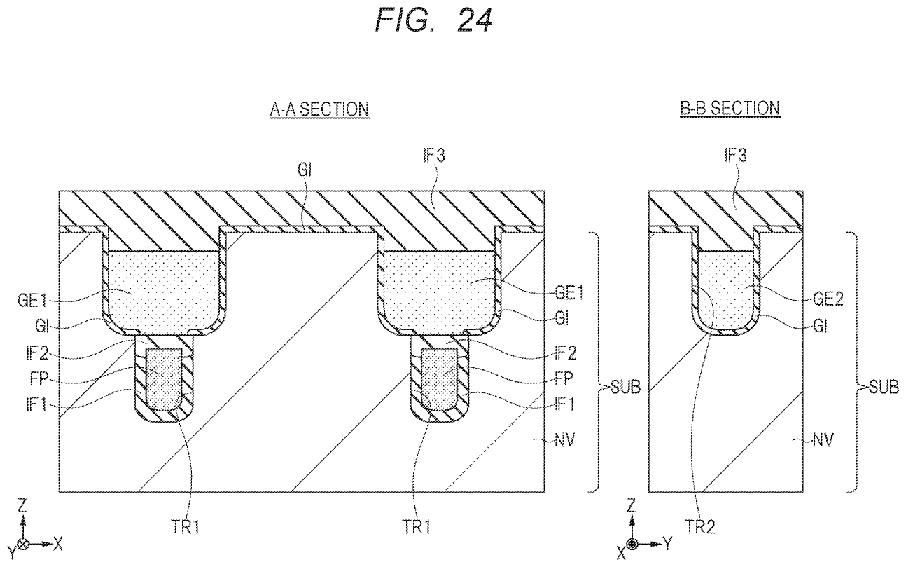

As shown in FIG. 24, an insulating film IF3 is formed on the upper surface TS of the semiconductor substrate SUB by, for example, a CVD method so as to cover the upper surface of each of the gate electrode GE1 and the gate electrode GE2.

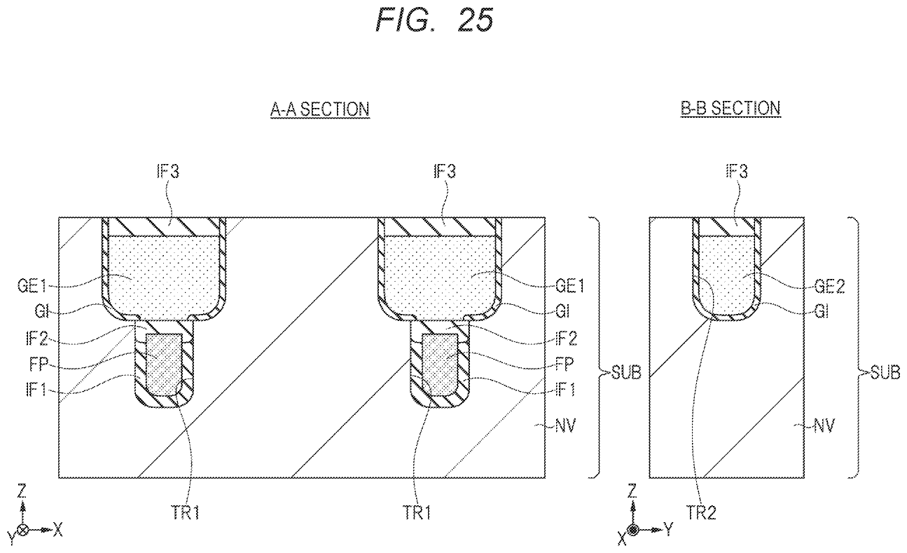

As shown in FIG. 25, the insulating film IF3 is subjected to an anisotropic etch process. As a result, the insulating films IF3 and gate insulating film GI on the upper surface TS of the semiconductor substrate SUB are removed, and the insulating film IF3 is left on each of the upper surfaces of the gate electrode GE1 and the gate electrode GE2.

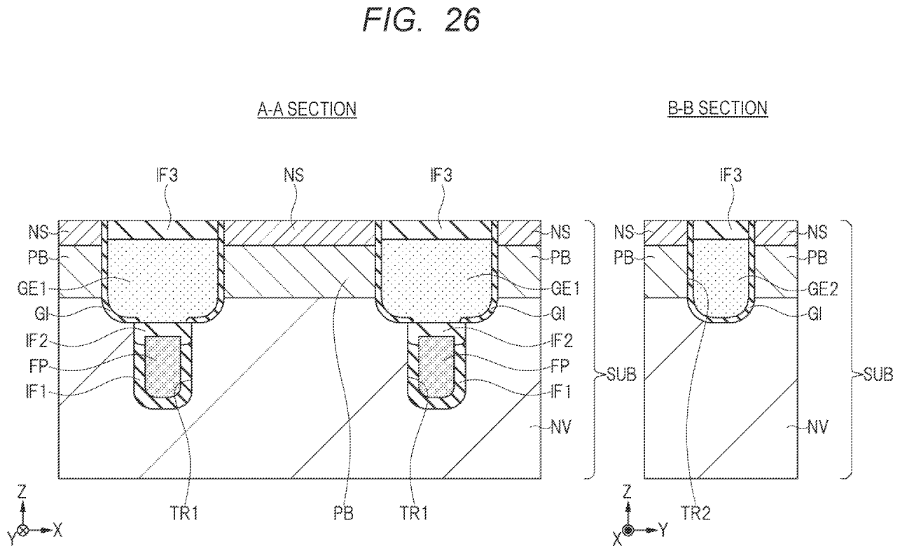

As shown in FIG. 26, a body region PB and a source region NS are formed in the semiconductor substrate SUB.

First, a p-type body region PB is selectively formed on the semiconductor substrate SUB by introducing, for example, boron (B) by photolithography and ion-implantation. The body region PB is formed to be shallower than the depth of each of the trench TR1 and the trench TR2.

Next, an n-type source region NS is selectively formed in the body region PB by introducing arsenic (As), for example, by a photolithography technique and an ion-implantation method. Thereafter, the semiconductor substrate SUB is subjected to a heat treatment to activate impurities contained in the source region NS and the body region PB.

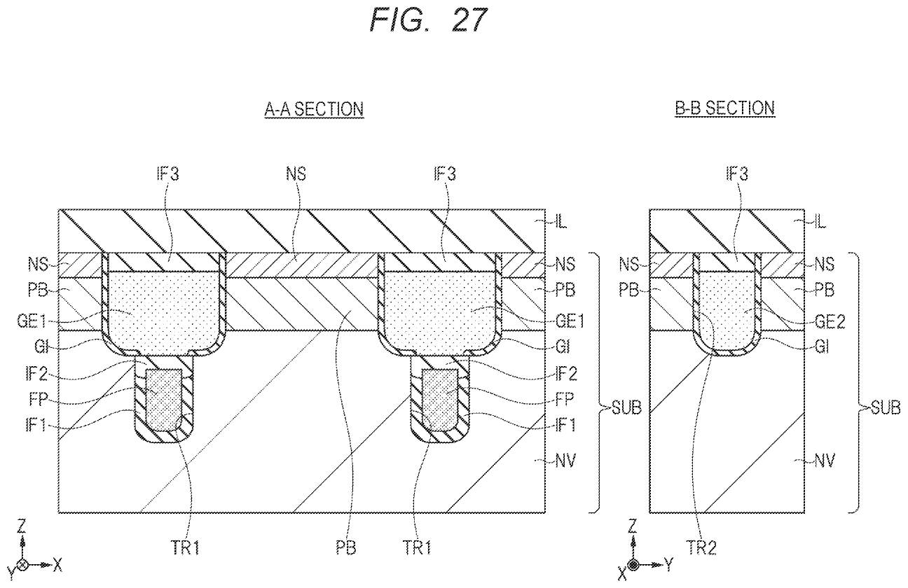

As shown in FIG. 27, the interlayer insulating film IL is formed on the upper surface TS of the semiconductor substrate SUB by, for example, a CVD method so as to cover the trench TR1 and the trench TR2.

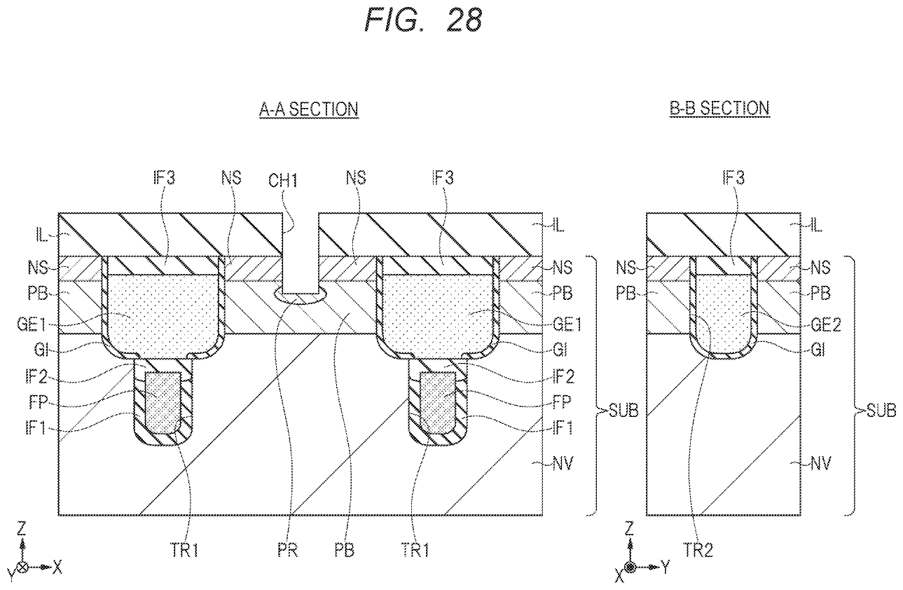

As shown in FIG. 28, a hole CH1 and a high concentration diffusion region PR are formed.

First, on the interlayer insulating film IL, a resist pattern having a pattern for opening the semiconductor substrate SUB in which the source region NS is formed is formed. Next, an anisotropic etch process is performed using the resist pattern as a mask to form a hole CH1 going through the interlayer insulating film IL and the source region NS and reaching the inside of the body region PB. Next, a p-type high concentration diffusion region PR is formed by introducing, for example, boron (B) into the body region PB at the bottom of the hole CH1 by the ion-implantation method. Thereafter, the resist pattern is removed by an ashing process.

Note that the bottom of the hole CH1 does not reach the gate electrode GE2 at a position where the hole CH1 intersects the trench TR2, and is located on the insulating film IF3 (see FIG. 6).

For example, when the interlayer insulating film IL and the insulating film IF3 are made of the same kind of material such as a silicon oxide film, the etching gas is switched after the over-etching of a degree at which the insulating film IF3 is not penetrated is performed when the hole CH1 reaches the semiconductor substrate SUB. The anisotropic etching process is continued under the condition that the semiconductor substrate SUB is easily etched and the insulating film IF3 is hardly etched. When the hole CH1 goes through the source region NS and reaches the body region PB, the anisotropic etch process is terminated.

In addition, when the insulating film IF3 is made of a material such as a silicon nitride film other than the interlayer insulating film IL, the insulating film IF3 can function as an etching stopper film when the hole CH1 is formed, so that the possibility that the hole CH1 reaches the gate electrode GE2 can be suppressed more reliably.

Next, although not illustrated here, a hole CH2 and a hole CH3 are formed in the interlayer insulating film IL (see FIG. 7).

First, a resist pattern having a pattern for making an opening on the contact portion FPa and on the lead-out portion GEa is formed on the interlayer insulating film IL. Next, an anisotropic etch process is performed using the resist pattern as a mask to form a hole CH2 and a hole CH3 going through the interlayer insulating film IL and the insulating film IF3. The hole CH2 reaches the contact portion FPa, and the hole CH3 reaches the lead-out portion GEa. Thereafter, the resist pattern is removed by an ashing process.

The order in which the hole CH1 is formed and the order in which the hole CH2 and the hole CH3 are formed may be any order.

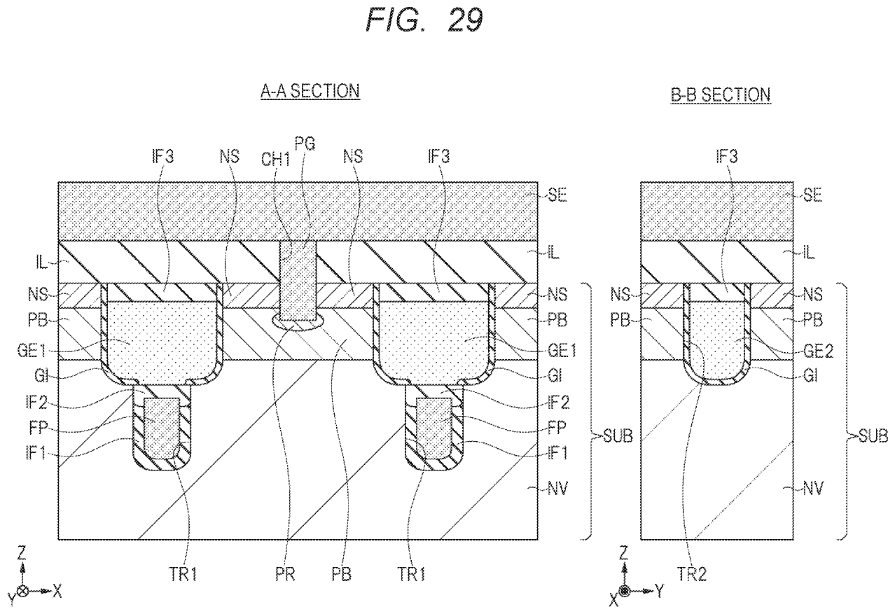

As shown in FIG. 29, a plug PG is formed inside the hole CH1, and a source electrode SE is formed on the interlayer insulating film IL.

First, a first barrier metal film is formed inside the hole CH1 and on the interlayer insulating film IL by a sputtering method or a CVD method. The first barrier metal film is formed of, for example, a laminated film of a titanium nitride film and a titanium film. Next, a first conductive film is formed on the first barrier metal film by CVD method. The first conductive film is formed of, for example, a tungsten film.

Next, the first barrier metal film and the first conductive film formed outside the hole CH1 is removed by polishing using CMP method or anisotropic etching. As a result, a plug PG made of the first barrier metal film and the first conductive film is formed so as to fill the inside of the hole CH1. Through these steps, a plug PG is also formed inside each of the hole CH2 and the hole CH3.

Next, a second barrier metal film is formed on the interlayer insulating film IL by sputtering. The second barrier metal film is formed of, for example, a titanium tungsten film. Next, a second conductive film is formed on the second barrier metal film by sputtering. The second conductive film is, for example, an aluminum alloy film to which copper or silicon is added. Next, the source electrode SE is formed by patterning the second barrier metal film and the second conductive film. Through these steps, a gate wiring GW is also formed on the interlayer insulating film IL.

Next, although not illustrated here, a protective film made of, for example, a polyimide film is formed on the source-electrode SE and the gate wiring GW by, for example, a coating method. By forming openings in parts of the protective film, regions of the source electrode SE and the gate wiring GW that become the source pad SP and the gate pad GP are exposed.

Thereafter, the structure shown in FIG. 5 is obtained through the following manufacturing process. First, the bottom surface BS of the semiconductor substrate SUB is polished as needed. Next, an n-type drain-region ND is formed by introducing, for example, arsenic (As) or the like into the lower surface BS of the semiconductor substrate SUB by ion-implantation. When the semiconductor substrate SUB is composed of a stack of an n-type silicon substrate and an n-type semiconductor layer, the high-concentration n-type silicon substrate forms a drain region ND, and thus forming of the drain region ND by the ion-implantation described above can be omitted. Next, a drain-electrode DE is formed under the lower surface BS of the semiconductor substrate SUB by a sputtering method.

### First Modified Example

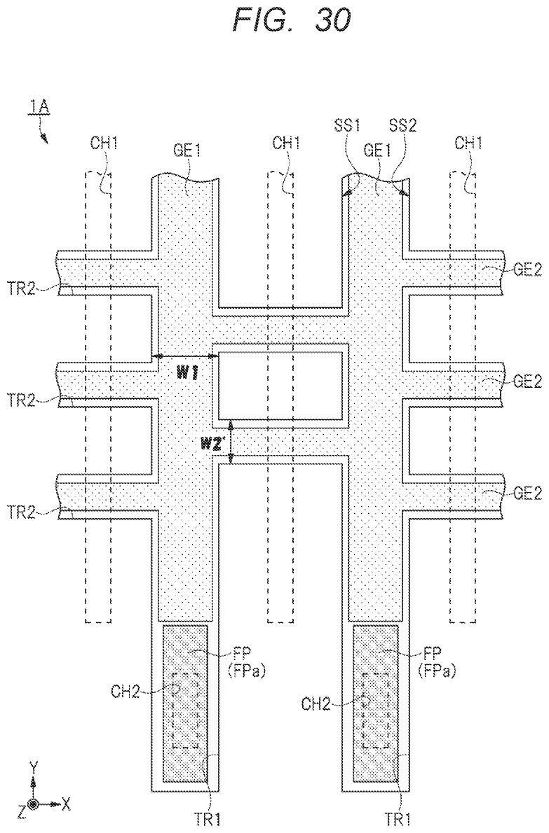

Hereinafter, the semiconductor device 100 in a first modified example of the first embodiment will be described with reference to FIG. 30.

In the first embodiment, as shown in FIG. 3, the plurality of trenches TR2 on the side surface SS1 side and the plurality of trenches TR2 on the side surface SS2 side are arranged in line symmetry with respect to the trench TR1 in plan view.

In the first modified example, as shown in FIG. 30, the plurality of trenches TR2 on the side surface SS1 side and the plurality of trenches TR2 on the side surface SS2 side are arranged in a staggered arrangement in plan view. In other words, a portion where the trench TR2 on the side surface SS1 side communicates with the trench TR1 and a portion where the trench TR2 on the side surface SS2 side communicates with the trench TR1 are shifted from each other in the Y-direction. In other words, in the first embodiment, a portion where the trench TR2 communicates with the trench TR1 forms a “cross path”, while a portion where the trench TR2 communicates with the trench TR1 forms a “T path” in the first modified example.

According to further studies by the inventors of the present application, it was found that when the communicating portion forms a “cross path”, the embeddability of each of the conductive film CF1 and the conductive film CF2 at the communicating portions tends to be lower than that at other portions at the time of the step of forming the conductive film CF1 of FIG. 15 and the step of forming the conductive film CF2 of FIG. 22. When the embeddability is low, it becomes difficult to align the height of each of the field plate electrode FP or the gate electrode GE2 at the communicating portion with the height of other portions.

Therefore, as in the first modified example, by setting the communication portion to be a “T-path”, the embeddability of each of the conductive film CF1 and the conductive film CF2 is improved as compared with the “cross-path”. In the step of forming the field plate electrode FP and the gate electrode GE2, the conductive film CF1 and the conductive film CF2 are subjected to a polishing treatment by a CMP method, and then subjected to an anisotropic etching treatment. When the uniformity of the height is not improved by the polishing treatment, the technique of the first modified example is effective.

### Second Modified Example

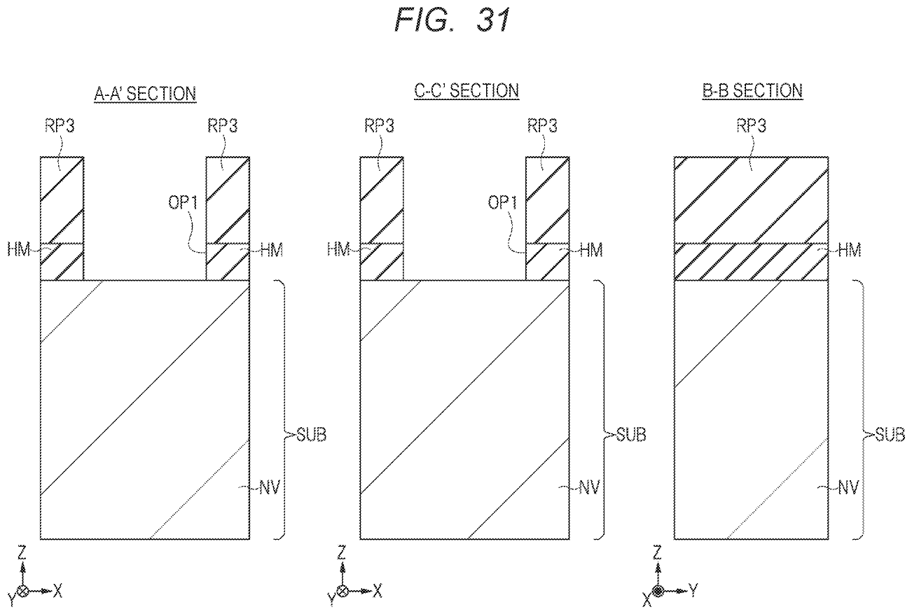

A manufacturing method of the semiconductor device 100 in the second modified example of the first embodiment will be described below with reference to FIG. 31 to FIG. 35. A-A′ cross section, C-C′ cross section, and B-B cross section shown in FIGS. 31 to 35 are cross-sectional views along A-A′ line, C-C′ line, and B-B line shown in FIG. 3, respectively.

In the first embodiment, as shown in FIG. 9, when a hard mask HM is selectively formed on the upper surface TS of a semiconductor substrate SUB, an opening OP1 and an opening OP2 are formed using a resist pattern RP1.

However, according to a further study by the present inventors, when a pattern of a trench TR1 having a wide width W1 and a pattern of a trench TR2 having a narrow width W2 are simultaneously exposed to one resist pattern RP1, the width of one pattern is likely to be close to the width of the other pattern. That is, when it is attempted to increase the accuracy of the pattern of the trench TR1, the width of the pattern of the trench TR2 is likely to be wider than designed. In addition, when it is attempted to increase the accuracy of the pattern of the trench TR2, the width of the pattern of the trench TR1 is likely to be narrower than designed.

In the second modified example, an opening OP1 and an opening OP2 are formed using different resist patterns. That is, the opening OP1 is formed using the resist pattern RP3, and the opening OP2 is formed using the resist pattern RP4.

As shown in FIG. 31, first, a hard mask HM is formed on the upper surface TS of the semiconductor substrate SUB by, for example, a CVD method. Next, a resist pattern RP3 is selectively formed on the hard mask HM. Next, an anisotropic etch process is performed using the resist pattern RP3 as a mask to form an opening OP1 in the hard mask HM. Since the resist pattern RP3 covers the hard mask HM of B-B cross section, no opening OP2 for the trench TR2 is formed at this stage. Thereafter, the resist pattern RP3 is removed by ashing.

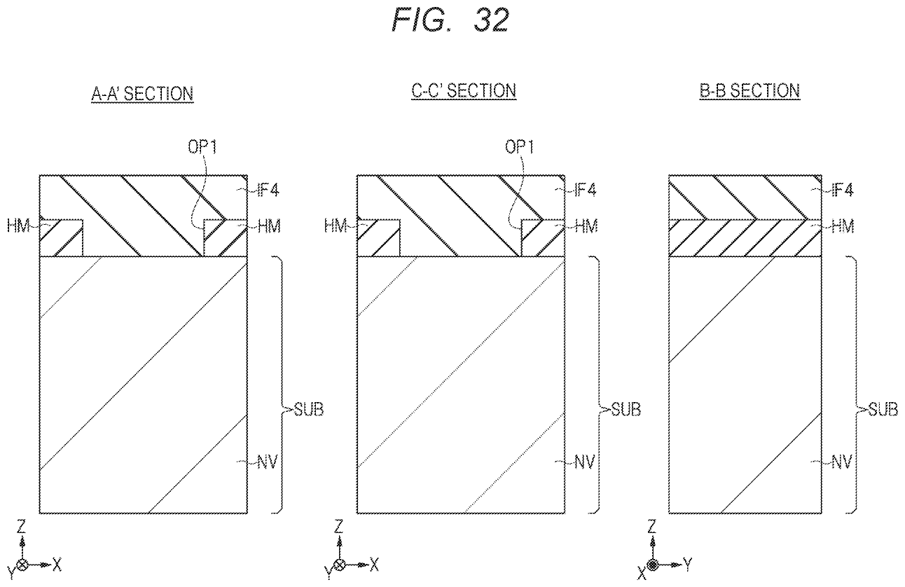

As shown in FIG. 32, first, an insulating film IF4 is formed on the hard mask HM and inside the opening OP1 so as to fill the opening OP1, for example, by CVD. The insulating film IF4 is made of a material other than the hard mask HM, and is, for example, a silicon-oxide film. Next, the upper surface of the insulating film IF4 is planarized by a polishing process using a CMP method.

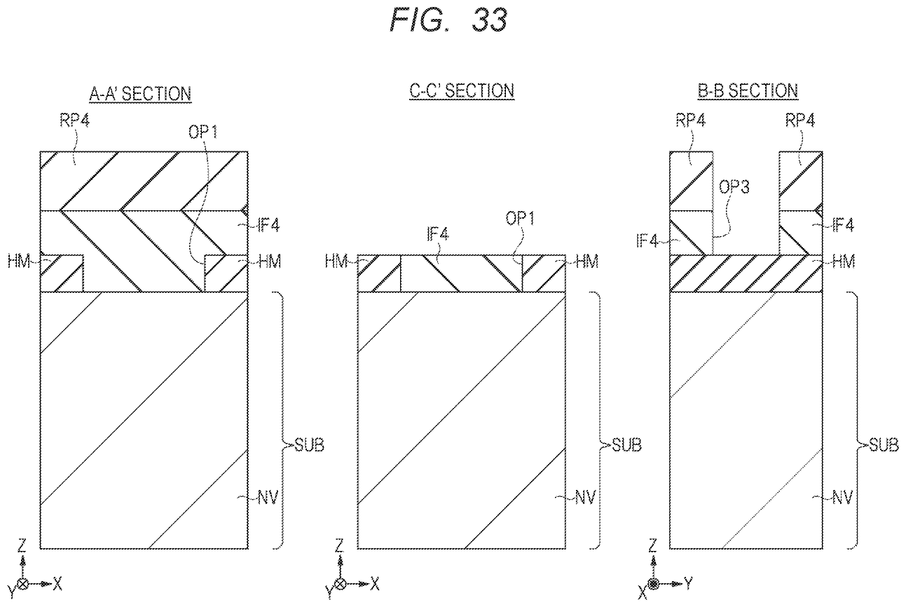

As shown in FIG. 33, first, a resist pattern RP4 is selectively formed on the insulating film IF4. Next, an anisotropic etch process is performed using the resist pattern RP4 as a mask to form an opening OP3 in the insulating film IF4. At this stage, the hard mask HM which was not covered with the resist pattern RP4 is exposed from the insulating film IF4. Thereafter, the resist pattern RP4 is removed by ashing.

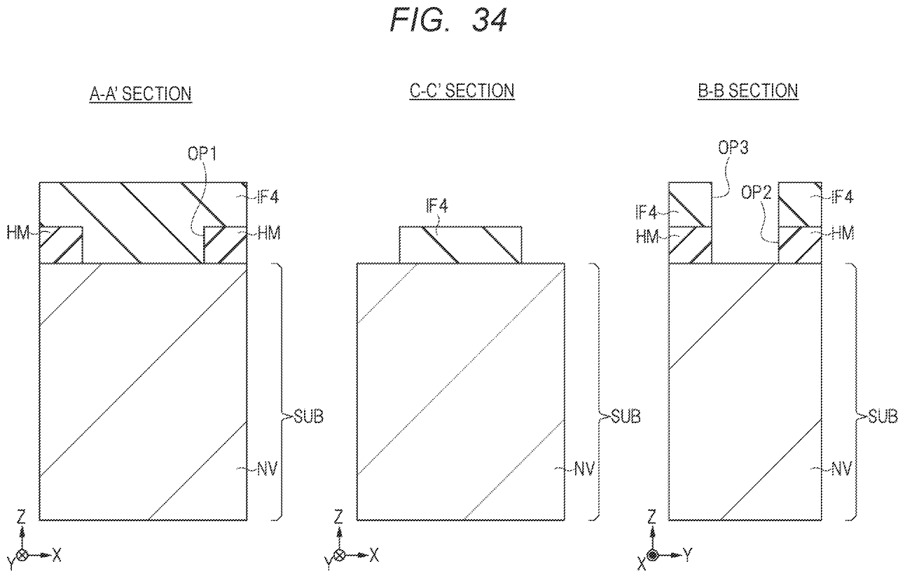

As shown in FIG. 34, the opening OP2 is formed in the hard mask HM exposed from the opening OP3 by performing an anisotropic etch process using the insulating film IF4 as a mask. That is, the hard mask HM exposed from the insulating film IF4 is removed.

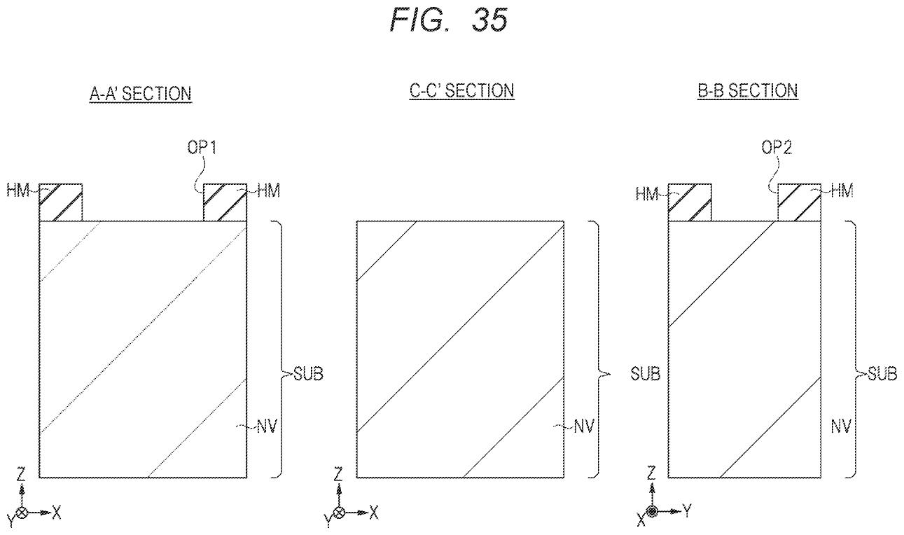

As shown in FIG. 35, the insulating film IF4 is removed by an isotropic etching process using, for example, a solution containing hydrofluoric acid. Subsequent manufacturing steps are the same as those in FIG. 10 and thereafter.

As described above, in the second modified example, since the opening OP1 and the opening OP2 are formed in the hard mask HM by using the different resist patterns RP3, RP4, the accuracy of the pattern of each of the trench TR1 and the trench TR2 can be improved.

Note that the technique described in the second modified example can also be applied to the first modified example.

### Third Modified Example

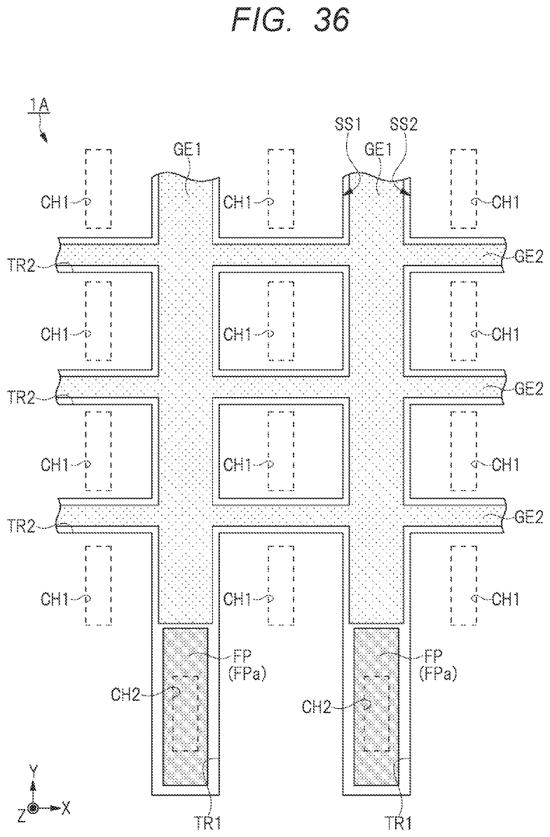

Hereinafter, the semiconductor device 100 in the third modified example of the first embodiment will be described with reference to FIG. 36.

In the first embodiment, as shown in FIG. 3, the hole CH1 extends in the Y-direction and intersects the trench TR2 in plan view.

In the third modified example, as shown in FIG. 36, the hole CH1 extending in the Y-direction are divided into a plurality of portions, and one hole CH1 is formed between the respective trenches TR2. Since the hole CH1 does not intersect the trench TR2 in plan view, the possibility that the hole CH1 reaches the gate electrode GE2 is easily suppressed. Such the third modified example is useful when the distance between the trenches TR2 is wide enough to allow one hole CH1 to be placed.

However, if the distance between the trenches TR2 is made as small as possible and a large number of gate electrodes GE2 are arranged, the on-resistance can be further reduced. In other words, in terms of suppressing the possibility that the hole CH1 reaches the gate electrode GE2, third modified example is superior to the first embodiment, but in terms of reducing the on-resistance, the first embodiment is superior to the third modified example.

Note that the technique described in the third modified example can also be applied to the first modified example and the second modified example.

Although the present invention has been described in detail based on the above-described embodiments, the present invention is not limited to the above-described embodiments and can be variously modified without departing from the gist thereof.

For example, in order to improve the breakdown voltage of the outer periphery of the semiconductor device 100, a peripheral trench may be provided in the semiconductor substrate SUB along the pair of outer edges 20 and the pair of outer edges 30. That is, as described with reference to FIGS. 3 and 4, an outer peripheral trench extending in the X direction on the lower side of the trench TR1 of FIG. 3 and extending in the Y direction on the right side of the lead-out trench TRa of FIG. 4 may be provided. In the outer peripheral trench, an outer peripheral electrode is formed in the same structure as the contact portion FPa. In such cases, a hole and a plug PG are formed in the interlayer insulating film IL on the outer peripheral electrode extending in the X-direction on the lower side of the trench TR1 in FIG. 3, and the source electrode SE is extended to the upper side of the outer peripheral electrode. Thus, the source potential can be supplied from the source electrode SE to the outer peripheral electrode through the hole (plug PG).

What is claimed is:

1. A semiconductor device comprising:
a semiconductor substrate of a first conductivity type having an upper surface and a lower surface;
a first trench formed in the semiconductor substrate so as to reach a predetermined depth from the upper surface of the semiconductor substrate;
a field plate electrode formed at a lower portion of the first trench inside the first trench and electrically isolated from the semiconductor substrate;
a first gate electrode formed at an upper portion of the first trench inside the first trench and electrically isolated from the semiconductor substrate and the field plate electrode;
a second trench formed in the semiconductor substrate so as to reach a predetermined depth from the upper surface of the semiconductor substrate; and
a second gate electrode formed inside the second trench and electrically isolated from the semiconductor substrate,
wherein a depth of the first trench is greater than a depth of the second trench;
wherein the first trench extends in a first direction in plan view;
wherein the second trench extends in a second direction intersecting the first direction in plan view;
wherein the first trench and the second trench communicate with each other; and
wherein the first gate electrode and the second gate electrode are integrated with each other.

2. The semiconductor device according to claim 1, wherein an electrode other than the second gate electrode is not formed inside the second trench.

3. The semiconductor device according to claim 1, wherein a gate potential is supplied to each of the first gate electrode and the second gate electrode, a source potential is supplied to the field plate electrode, and a drain potential is supplied to the semiconductor substrate.

4. The semiconductor device according to claim 3, further comprising:
a body region of a second conductivity type opposite to the first conductivity type which is formed in the semiconductor substrate so that a depth from the upper surface of the semiconductor substrate is shallower than a depth of each of the first trench and the second trench;
a source region of the first conductivity type formed in the body region;
an interlayer insulating film formed on the upper surface of the semiconductor substrate so as to cover the first trench and the second trench;
a first hole formed in the interlayer insulating film and reaching the source region and the body region;
a source electrode and a gate wiring formed on the interlayer insulating film; and
a drain electrode formed below the lower surface of the semiconductor substrate,
wherein the source electrode is electrically connected to the source region and the body region via the first hole,
wherein, in plan view, the first hole extends in the first direction, adjoins the first trench, and intersects with the second trench;
wherein, inside the second trench, a first insulating film is formed on the second gate electrode; and
wherein a bottom portion of the first hole is located on the first insulating film at a position where the first hole intersects with the second trench.

5. The semiconductor device according to claim 4,
wherein a portion of the field plate electrode is formed not only in the lower portion of the first trench but also in the upper portion of the first trench inside the first trench, and forms a contact portion of the field plate electrode; and
wherein a second hole reaching the contact portion is formed in the interlayer insulating film; and
wherein the source electrode is electrically connected to the contact portion via the second hole.

6. The semiconductor device according to claim 5, further comprising:
a lead-out trench formed in the semiconductor substrate so as to reach a predetermined depth from the upper surface of the semiconductor substrate and communicating with the second trench; and
a lead-out portion formed in the lead-out trench, electrically isolated from the semiconductor substrate, and integrated with the second gate electrode,
wherein a plurality of second trenches is formed in the semiconductor substrate;
wherein the lead-out trench extends in the first direction and communicates with the plurality of second trenches;
wherein a third hole reaching the lead-out portion is formed in the interlayer insulating film; and
wherein the gate wiring is electrically connected to the lead-out portion via the third hole.

7. The semiconductor device according to claim 6,
wherein the contact portion is provided in a terminal portion of the first trench in the first direction; and
wherein the lead-out trench is provided so as to communicate with a terminal portion of the second trench in the second direction.

8. The semiconductor device according to claim 6, wherein a width of the second trench in the first direction is narrower than a width of the upper portion of the first trench in the second direction.

9. The semiconductor device according to claim 8, wherein a width of the lead-out trench in the second direction is wider than a width of the second trench in the first direction.

10. The semiconductor device according to claim 1,
wherein the first trench has a first side surface and a second side surface opposed to the first side surface in the second direction;
wherein a plurality of the second trenches communicating with the first trench on the first side surface side is formed in the semiconductor substrate on the first side surface side;
wherein a plurality of the second trenches communicating with the first trench on the second side surface side is formed in the semiconductor substrate on the second side surface side; and
wherein the plurality of the second trenches on the first side surface side and the plurality of the second trenches on the second side surface side are arranged in line symmetry about the first trench in plan view.

11. The semiconductor device according to claim 1,
wherein the first trench has a first side surface and a second side surface opposed to the first side surface in the second direction;
wherein a plurality of the second trenches communicating with the first trench on the first side surface side is formed in the semiconductor substrate on the first side surface side;
wherein a plurality of the second trenches communicating with the first trench on the second side surface side is formed in the semiconductor substrate on the second side surface side; and
wherein the plurality of the second trenches on the first side surface side and the plurality of the second trenches on the second side surface side are staggered in plan view.

12. A method of manufacturing a semiconductor device, comprising:
(a) preparing a semiconductor substrate of a first conductivity type having an upper surface and a lower surface;
(b) after (a), forming a first trench and a second trench in the semiconductor substrate so as to reach a predetermined depth from the upper surface of the semiconductor substrate;
(c) after (b), selectively deepening the depth of the first trench so that the depth of the first trench becomes deeper than the depth of the second trench;
(d) after (c), forming a first insulating film, on the upper surface of the semiconductor substrate, inside the first trench, and inside the second trench;
(e) after (d), forming a first conductive film on the first insulating film so as to fill the inside of the first trench and the inside of the second trench;
(f) after (e), removing the first conductive film located outside the first trench and outside the second trench to form the first conductive film left inside the first trench and inside the second trench as a field plate electrode;
(g) after (f), removing the field plate electrode inside the second trench and retreating the field plate electrode inside the first trench toward the bottom of the first trench;
(h) after (g), removing the first insulating film located on the upper surface of the semiconductor substrate and inside the second trench and retreating the first insulating film inside the first trench toward the bottom of the first trench so that the position of the upper surface of the first insulating film located inside the first trench is lower than the position of the upper surface of the field plate electrode;
(i) after (h), selectively forming a second insulating film so as to cover the field plate electrode exposed from the first insulating film inside the first trench;
(j) after (i), forming a first gate insulating film inside the first trench located on the second insulating film and forming a second gate insulating film inside the second trench;
(k) after (j), forming a second conductive film on the first gate insulating film, on the second insulating film, and on the second gate insulating film so as to fill the inside of the first trench and the inside of the second trench; and
(l) after (k), removing the second conductive film outside the first trench and outside the second trench to form the second conductive film left inside the first trench above the field plate electrode as a first gate electrode and form the second conductive film left inside the second trench as a second gate electrode,
wherein the first trench extends in a first direction in plan view,
wherein the second trench extends in a second direction intersecting the first direction in plan view;
wherein the first trench and the second trench communicate with each other; and
wherein the first gate electrode and the second gate electrode are integrated with each other.

13. The method of manufacturing a semiconductor device according to claim 12,
wherein (b) includes:
(b1) selectively forming a hard mask on the upper surface of the semiconductor substrate; and
(b2) after (b1), performing an anisotropic etching process using the hard mask as a mask to form the first trench and the second trench in the semiconductor substrate exposed from the hard mask; and
wherein (c) includes:
(c1) forming the first insulating film inside the first trench and inside the second trench on the hard mask so that the inside of the first trench is not completely filled, and the inside of the second trench is completely filled;
(c2) after (c1), performing an anisotropic etching process on the first insulating film to remove the first insulating film on the hard mask to process the first insulating film inside the first trench into a sidewall shape while leaving the first insulating film inside the second trench;
(c3) after (c2), performing an anisotropic etching process using the hard mask and the first insulating film as masks to deepen the first trench; and
(c4) after (c3), sequentially removing the first insulating film and the hard mask.

14. The method of manufacturing a semiconductor device according to claim 13,
wherein (b1) includes:
(b11) forming the hard mask on the upper surface of the semiconductor substrate;
(b12) after (b11), selectively forming a first resist pattern on the hard mask;
(b13) after (b12), performing an anisotropic etching process using the first resist pattern as a mask to form a first opening and a second opening in the hard mask; and
(b14) after (b13), removing the first resist pattern; and
wherein, in (b2), the first trench is formed in the semiconductor substrate exposed at the first opening and the second trench is formed in the semiconductor substrate exposed at the second opening.

15. The method of manufacturing a semiconductor device according to claim 13, wherein (b1) includes:
(b11) forming a hard mask on the upper surface of the semiconductor substrate;
(b12) after (b11), selectively forming a first resist pattern on the hard mask;
(b13) after (b12), performing an anisotropic etching process using the first resist pattern as a mask to form a first opening in the hard mask;
(b14) after (b13), removing the first resist pattern;
(b15) after (b14), forming a second insulating film on the hard mask and inside the first opening to fill the first opening;
(b16) after (b15), selectively forming a second resist pattern on the second insulating film;
(b17) after (b16), performing an anisotropic etching process using the second resist pattern as a mask to form a third opening in the second insulating film;
(b18) after (b17), removing the second resist pattern;
(b19) after (b18), performing an anisotropic etching process using the second insulating film as a mask to form a second opening in the hard mask exposed at the third opening; and
(b20) after (b19), removing the second insulating film,
wherein, in (b2), the first trench is formed in the semiconductor substrate exposed at the first opening and the second trench is formed in the semiconductor substrate exposed at the second opening.

16. The method of manufacturing a semiconductor device according to claim 12, further comprising:
(m) after (l), retreating the first gate electrode and the second gate electrode so that the positions of upper surfaces of the first gate electrode and the second gate electrode are lower than the position of the upper surface of the semiconductor substrate;
(n) after (m), forming a third insulating film on the upper surface of the semiconductor substrate so as to cover the upper surfaces of the first gate electrode and the second gate electrode;
(o) after (n), performing an anisotropic etching process on the third insulating film to remove the third insulating film on the upper surface of the semiconductor substrate while leaving the third insulating film on the upper surfaces of the first gate electrode and the second gate electrode.

17. The method of manufacturing a semiconductor device according to claim 16, further comprising:
(p) after (i), forming a body region of a second conductivity type opposite to the first conductivity type in the semiconductor substrate so that a depth from the upper surface of the semiconductor substrate is shallower than a depth of each of the first trench and the second trench;
(q) after (p), forming a source region of the first conductivity type in the body region;
(r) after (q), forming an interlayer insulating film on the upper surface of the semiconductor substrate so as to cover the first trench and the second trench;
(s) after (r), forming a first hole in the interlayer insulating film so as to reach the source region and the body region;
(t) after (s), forming a source electrode and a gate wiring on the interlayer insulating film; and
(u) after (t), forming a drain electrode below the lower surface of the semiconductor substrate,
wherein the source electrode is electrically connected to the source region and the body region via the first hole;
wherein the drain electrode is electrically connected to the semiconductor substrate;
wherein, in plan view, the first hole extends in the first direction, adjoins the first trench, and intersects the second trench; and
wherein a bottom portion of the first hole is located on the third insulating film at a position where the first hole intersects the second trench.

18. The method of manufacturing a semiconductor device according to claim 17, wherein (g) includes:
(g1) forming a resist pattern on a portion of the field plate electrode inside the first trench;
(g2) removing the field plate electrode inside the second trench by performing an anisotropic etching process using the resist pattern as a mask, and retreating the other portion of the field plate electrode inside the first trench toward the bottom of the first trench so that the portion of the field plate electrode inside the first trench is left as a contact portion; and
(g3) removing the resist pattern,
wherein the method further comprises, between (r) and (t), forming a second hole reaching the contact portion in the interlayer insulating film; and
wherein the source electrode is electrically connected to the contact portion via the second hole.

19. The method of manufacturing a semiconductor device according to claim 18,
wherein, in (b), a lead-out trench is formed in the semiconductor substrate so as to reach a predetermined depth from the upper surface of the semiconductor substrate;
wherein, in (l), lead-out portion made of the second conductive film is formed inside the lead-out trench;
wherein, between (r) and (t), the method further includes forming a third hole reaching the lead-out portion in the interlayer insulating film;
wherein the lead-out trench is communicated with the second trench;
wherein the lead-out portion is integrated with the second gate electrode; and
wherein the gate wiring is electrically connected to the lead-out portion via the third hole.

20. The manufacturing method of a semiconductor device according to claim 19,
wherein the contact portion is provided in a terminal portion of the first trench in the first direction; and
wherein the lead-out trench is provided so as to communicate with a terminal portion of the second trench in the second direction.
